(19) United States
(12) Patent Application Publication
(10) Pub. No.: US 2017/0133202 A1
(43) Pub. Date: May 11, 2017

(54) COMPUTER ADDRESSABLE PLASMA DENSITY MODIFICATION FOR ETCH AND DEPOSITION PROCESSES

(71) Applicant: Lam Research Corporation, Fremont, CA (US)

(72) Inventor: Ivan L. Berry, III, San Jose, CA (US)

(21) Appl. No.: 14/936,437

(22) Filed: Nov. 9, 2015

(51) Int. Cl. H01J 37/32; C23C 16/455; H01L 21/3065; C23C 16/511; H01L 21/67; H01L 21/02

(52) U.S. Cl. CPC H01J 37/3222; H01L 21/67069; H01L 21/0228; H01L 21/3065; H01J 37/32926; H01J 37/32238; C23C 16/511; C23C 16/45544; C23C 16/45565; H01J 37/3244; H01J 2237/3341; H01J 2237/3321

(57) ABSTRACT

Disclosed herein are methods of modifying a reaction rate on a semiconductor substrate in a processing chamber which utilize a phased-array of microwave antennas. The methods may include energizing a plasma in a processing chamber, emitting a beam of microwave radiation from a phased-array of microwave antennas, and directing the beam into the plasma so as to cause a change in a reaction rate on the surface of a semiconductor substrate inside the processing chamber. Also disclosed herein are particular embodiments of phased-arrays of microwave antennas, as well as semiconductor processing apparatuses which include a phased-array of microwave antennas configured to emit a beam of microwave radiation into a processing chamber.

### BACKGROUND

Many classes of processes important in semiconductor fabrication involve the use of a gas plasma. Reactive ion etching (RIE) operations and atomic layer deposition (ALD) operations, for example, may involve the use of energetic plasma-phase ion and free-radical species to activate their associated surface reactions—surface etch reactions for the case of RIE and surface deposition reactions for the case of ALD. However, these processes do not always proceed with the ideal degree of uniformity across the entire surface of the substrate being processed. Many factors can affect across-wafer uniformity. For the case of plasma-based processes (and due to the highly energized nature of the plasma phase), it may be that it is difficult to maintain an ideally uniform plasma density in the spatial region where it contacts the substrate surface, and these differences in plasma density may lead to differential across-wafer activation of plasma-mediated surface reactions (whether deposition or etching). However, many other factors besides plasma characteristics may also contribute, in whole or in part, to wafer non-uniformity. Generally speaking, surface non-uniformities may be systematic to a particular process (perhaps specific to certain surface chemistries), they may be particular to a particular processing chamber's non-uniformities in design or construction, etc. Other systematic non-uniformities may include wafer center-to-edge non-uniformities occurring because of the intrinsic wafer size/geometry. Of course, substrate processing non-uniformities may also be random, e.g., the result of random fluctuations in reaction chamber process conditions, random wafer variation, etc. More typically, both systematic and random factors contribute to non-uniformities in substrate processing. What is sought are plasma-based techniques for dealing with improving overall process uniformity in these various scenarios.

### SUMMARY

Disclosed herein are methods of modifying a reaction rate on a semiconductor substrate in a processing chamber which utilize a phased-array of microwave antennas. The methods may include energizing a plasma in a processing chamber, emitting a beam of microwave radiation from a phased-array of microwave antennas, and directing the beam into the plasma so as to affect a change in a reaction rate on the surface of a semiconductor substrate inside the processing chamber.

Also disclosed herein are particular embodiments of phased-arrays of microwave antennas. In some embodiments, the phased-arrays of microwave antennas may include 5-256 microwave antennas arranged substantially in a plane with a mean spacing between adjacent antennas of 0.1-150 cm. In some embodiments, the phased-arrays of microwave antennas may include 8-256 microwave antennas arranged substantially cylindrically with respect to each other. In some embodiments, the height of said cylindrical arrangement may be 5-500 mm, and the diameter of said cylindrical arrangement may be 300-600 mm.

Also disclosed herein are semiconductor processing apparatuses which include a phased-array of microwave antennas configured to emit a beam of microwave radiation into a processing chamber. These apparatuses may include said processing chamber and phased-array of microwave antennas as well as a substrate holder configured to hold a semiconductor substrate within the processing chamber, a plasma generator configured to generate a plasma within the processing chamber, a controller having instructions for operating the phased-array microwave antenna to affect the plasma within the processing chamber.

### BRIEF DESCRIPTION OF THE DRAWINGS

FIGS. 1A-1D illustrate a phased-array of microwave antennas positioned relative to a substrate surface and generating one or more beams and/or spots of microwave energy directed towards a particular region or regions of the substrate surface.

FIG. 2A schematically illustrates an inductively coupled plasma reactor with a phased-array of microwave antennas located at the top of the semiconductor processing chamber of the reactor apparatus.

FIG. 2B schematically illustrates an inductively coupled plasma reactor with a phased-array of microwave antennas positioned around the periphery of the semiconductor processing chamber of the reactor apparatus.

FIG. 2C schematically illustrates a capacitively coupled plasma reactor with a phased-array of microwave antennas located at the top of the semiconductor processing chamber of the reactor apparatus.

FIG. 2D schematically illustrates the plate electrode from the capacitively coupled plasma reactor illustrated in FIG. 2C.

FIG. 2E schematically illustrates a capacitively coupled plasma reactor with a phased-array of microwave antennas positioned around the periphery of the semiconductor processing chamber of the reactor apparatus.

FIGS. 3A-1 through 3A-4 show a set of simulation results illustrating the controlled focusing of microwave radiation onto or near a prototypical substrate surface as generated from a computer model of a phased-array of 25 microwave antennas positioned at the top of a processing apparatus.

FIGS. 3B-1 through 3B-5 show another set of simulation results illustrating the controlled focusing of microwave radiation onto or near a prototypical substrate surface as generated from a computer model of a phased-array of 25 microwave antennas positioned at the top of a processing apparatus.

FIGS. 3C-1 through 3C-5 show another set of simulation results illustrating the controlled focusing of microwave radiation onto or near a prototypical substrate surface as generated from a computer model of a phased-array consisting of 25 microwave antennas positioned at the top of a processing apparatus.

FIGS. 3D-1 through 3D-7 show a set of simulation results illustrating the controlled focusing of microwave radiation onto or near a prototypical substrate surface as generated from a computer model of a phased-array consisting of 25 microwave antennas positioned at the periphery of a processing apparatus.

FIG. 4A is a cross-sectional schematic of a substrate processing apparatus having a processing chamber with a single process station.

FIG. 4B is a schematic of a 4-station substrate processing apparatus having a substrate handler robot for loading and unloading substrates from 2 process stations and a controller for operating the apparatus.

FIG. 5A is a cross-sectional schematic of a single-station processing chamber of a substrate processing apparatus appropriate for implementing various ALD and/or CVD processes which employs a chandelier-type showerhead and an associated showerhead collar, and featuring plasma feed and curtain gas flow paths.

FIG. 5B is a cross-sectional schematic of a dual-station processing chamber of a substrate processing apparatus appropriate for implementing various ALD and/or CVD processes, each processing station having a substrate holder and employing a chandelier-type showerhead and an associated showerhead collar.

FIGS. 6A-6C are schematics of a capacitively coupled plasma (CCP) reactor appropriate for implementing various etch processes.

FIG. 7 is a schematic of an inductively coupled plasma (ICP) reactor appropriate for implementing various etch processes.

FIG. 8 is a schematic of a substrate processing cluster tool appropriate for implementing various etch processes.

### DETAILED DESCRIPTION

In the following description, numerous specific details are set forth in order to provide a thorough understanding of the present invention. However, the present invention may be practiced without some or all of these specific details. In other instances, well known process operations have not been described in detail so as to not unnecessarily obscure the present invention. While the invention will be described in conjunction with specific detailed embodiments, it is to be understood that these specific detailed embodiments are not intended to limit the scope of the inventive concepts disclosed herein.

Although it is generally desired that wafer processing operations apply with uniform effect consistently across the entire surface of every wafer that is processed, such uniformity, of course, is not a reality. In reality, wafer processing operations exhibit across-wafer non-uniformity to varying degrees. In some cases, non-uniformities in a deposited and/or etched film may have resulted from prior (upstream) processing operations (whether or not plasma-based). In some cases, non-uniformities may be anticipated to result from subsequent (downstream) processing operations (again, whether or not plasma-based). It is thus the task of the process engineer to devise effective strategies for dealing with processing non-uniformity—either, in the first instance, by preventing or minimizing it, or otherwise by compensating for it after it occurs, in some cases, at multiple stages of a processing workflow.

For surface-local processes, including surface etch processes and atomic layer deposition (ALD) processes, across-wafer uniformity depends on the reaction rates across the surface, which themselves depend on the incoming flux density of impacting and/or adsorbing reactants, any relevant sticking and/or adsorption coefficients, the outgoing fluxes of by-products, and the temperatures and pressures at the surface to the extent that the reactions are temperature and/or pressure sensitive. In addition, for surface reactions that require or are enhanced by one or more external source(s) of activation energy, such as plasma-based/enhanced etch or deposition processes, the across wafer reaction rates also depend on the density (and/or energy density) of the source of the activation energy. It should be understood that such an external activation energy source could, depending on the embodiment, serve to activate inbound/impinging chemical species to their reactive state(s) prior to their reaching the substrate surface (such as is typical in reactive ion etch (RIE) processes), or may serve to activate surface adsorbed reactants (such as is typical in atomic layer deposition (ALD) processes or a plasma enhanced chemical vapor deposition (PECVD) process). Thus, in the context of semiconductor processing operations involving surface reactions, one way of generally dealing with processing non-uniformity is to employ techniques which alter surface reaction rates locally—in particular locations and/or regions of the substrate surface—either to compensate for anticipated (downstream) systematic non-uniformities on the substrate surface, to remedy past (upstream) random non-uniformities, or to compensate for those arising in the instant surface reactive processing step (such as if an etch process tends to be non-uniform in the absence of any compensation), or all of the above.

It is noted that local temperature adjustment/control is one mechanism which can be used—and has successfully been used—to locally adjust and/or control surface reaction rates. One way local temperature control can be achieved is through the use of an array of heat-generating resistive elements located beneath the substrate when positioned in the etch chamber—e.g., inside or beneath the wafer chuck—so that by individually controlling current through each resistive element, substrate temperatures can be locally modified. While this design has typically been applied in the context of local etch rate adjustment, it can also, in principle, be applied to adjust film-forming reaction rates in ALD or PECVD processes. However, in either case, the extent to which such local temperature control can be effectively used to alter reaction rates—whether etch rates or deposition rates—depends on the extent to which the reaction rate of the particular etch or deposition process being employed is temperature sensitive. Some etch or deposition processes, though, may not be particularly temperature sensitive, and moreover, in some cases, for purposes of improving process stability, it may actually be desirable to employ an etch or deposition process which is temperature insensitive (or only exhibiting a weak sensitivity to temperature)—and for these classes of processes, reaction rate adjustment through temperature control is not feasible. Thus, although local temperature control does provide a mechanism for locally adjusting reaction rates (deposition or etch) in some scenarios, it is not without its drawbacks.

However, there are other mechanism that may also be employed to locally adjust surface reaction rates, because (as indicated above) in addition to a general dependence on temperature, surface reaction rates also typically depend on various other factors. For the case of an etch process, etch rates generally depend on the local density of activated etchant species, and so if the etchant is plasma activated (e.g., from a plasma dissociation event) then the local plasma density will also have a strong influence on etch rates. Accordingly, for these processes, control of local plasma density provides a viable mechanism for local etch rate adjustment/control. As mentioned, this has the benefit of allowing more freedom in choosing the etch reaction to be employed, because a temperature-dependent etch reaction is no longer required for local etch rate control and it may not even be desirable (based on process stability considerations).

To effect this etch rate control, plasma density may be adjusted through a variety of mechanisms, but many of these are not capable of effectively causing wafer location/region-specific modifications to plasma density. For instance, although plasma density in typical plasma reactor (e.g., for plasma-based etching) is a function of the gas composition, gas flow rate, applied electrical bias, RF power levels, frequencies, duty cycles, electrical energy distribution, surface recombination events, etc., in general, each of these factors are established and for the most part fixed by the plasma reactor design itself. It is true that a given design allows for some flexibility as to the choice of some of these parameters, and that plasma density may be varied through variation of these parameters—e.g., gas flow, pressure, applied RF power—but such adjustments generally result in global changes to plasma density across the reactor volume, rather than having a targeted effect on plasma density in specific locations/regions.

Thus, surface local adjustments of reaction rates (for deposition or etch)—e.g., to adjust the rate at a specific region on the wafer, without effecting rates at other regions—requires an additional type of plasma density control mechanism. One mechanism through which this can be achieved is the selectively targeted application of microwave radiation. It is understood that microwave radiation can be used to ionize molecules and increase plasma density, and there are a variety of commercial plasma etchers available which use microwave radiation as the main or even exclusive source of power for plasma generation. However, none of these tools use targeted microwave radiation to provide fine local, spatially resolved, control of plasma density in the vicinity of the substrate surface.

Accordingly, illustrated and described herein are methods and apparatuses for accomplishing targeted, spatially-local plasma density adjustment/control in the vicinity of the substrate surface through targeted application of microwave (MW) radiation, and in particular, methods and apparatuses which make use of phased-arrays of microwave antennas/emitters to generate microwave radiation of differential/non-uniform intensity across a substrate surface. The methods thus generally may involve the energizing of a plasma in a processing chamber, the emission of a beam of microwave radiation from a phased-array of microwave antennas associated with the processing chamber, and finally the directing of the beam of MW radiation into the energized plasma so as to affect an energy density of the plasma and thereby cause a change in a reaction rate on the surface of a semiconductor substrate inside the processing chamber. The methods and apparatuses may be applicable, depending on the embodiment, to spatially-local adjustment and/or control of plasma-activated (and/or enhanced) etch processes, plasma-activated (and/or enhanced) atomic layer deposition (ALD) processes, plasma enhanced chemical deposition (PECVD) processes, or generally to classes of reactive processes which are plasma-activated (and/or enhanced) at, near, or on the surface of a semiconductor substrate.

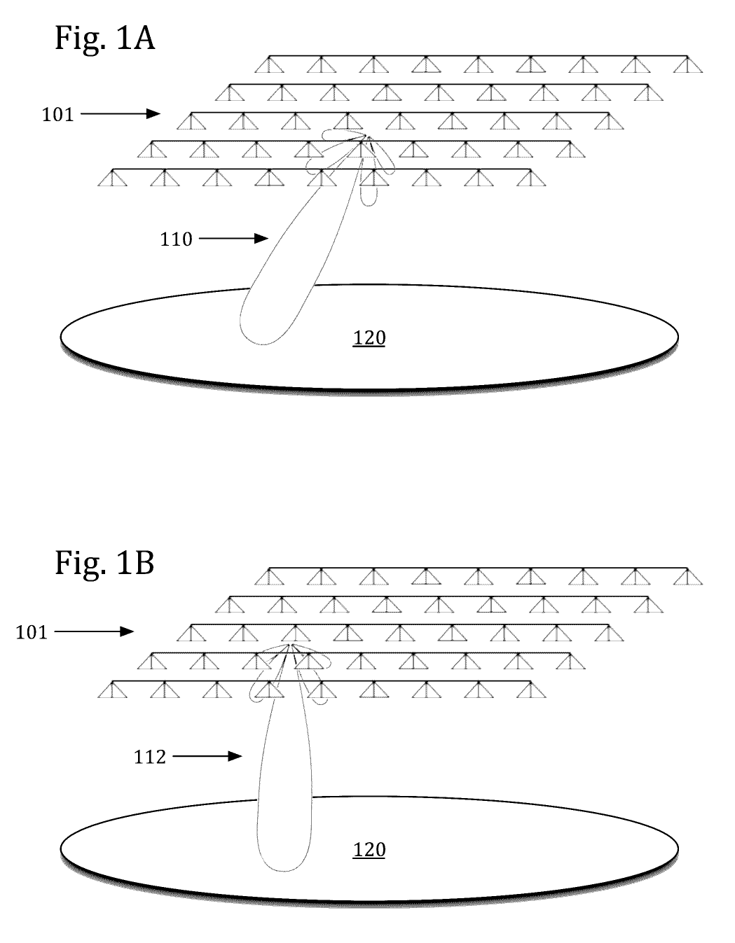

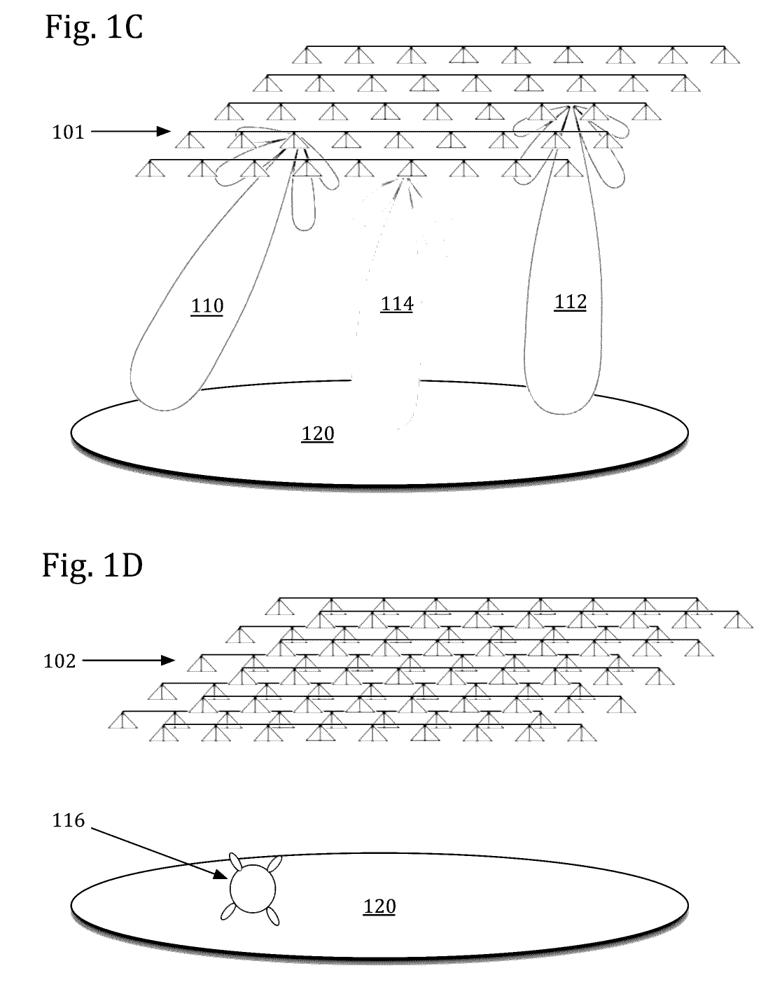

The basic principle is illustrated in FIG. 1A which shows a phased-array of microwave antennas (PAMA) 101 (similar, for example, to those used in commercial radar systems) positioned relative to a substrate surface 120 and generating a “beam” of microwave energy 110 directed towards a particular region of the substrate surface. Examples of phased microwave antenna arrays may be found in “Integrated Phased Array Systems in Silicon,” ALI HAJIMIRI, HOSSEIN HASHEMI, ARUN NATARAJAN, XIANG GUAN, AND ABBAS KOMIJANI, IEEE PROCEEDINGS OF THE IEEE, VOL. 93, NO. 9, (SEPTEMBER 2005), and “Microwave Theory of Phased-Array Antennas—A Review”, Louis Stark, PROCEEDINGS OF THE IEEE, VOL. 62, NO. 12, DECEMBER 1974, each of which is hereby incorporated by reference in its entirety for all purposes. As one of ordinary skill in the art will readily appreciate, in general, a phased-array of microwave antennas is an antenna array which allows the phases and/or amplitudes of MW radiation emitted from the various antennas of the array to be varied with respect to each other—i.e., the relative phases and/or amplitudes of microwave radiation emitted from (at least some) of the antennas of the array may be adjusted. In some embodiments, only the relative phases are varied; in other embodiments, only the relative amplitudes are varied, in other embodiments, the relative phases and the relative amplitudes of the antennas of the array are varied with respect to each other. Additionally, in some embodiments, the MW frequency, and/or frequencies, and/or range of frequencies emitted from the array may be varied, and in certain such embodiments, varied differently at different antennas of the phased-array. (Suitable MW frequency ranges include 1-500 GHz.) With such a phased-array of microwave antennas (PAMA) 101, direction and control of microwave intensity may be accomplished by adjusting, individually, the phases and/or amplitudes and/or directions of microwave radiation being emitted from 2 or more antennas of the PAMA (e.g., 3, 4, 5, 6, 7, 8, 9, 10, 11, 12, or more antennas of the PAMA), or even from each antenna of the PAMA. In this manner, an appropriate superposition of wave fronts may be generated that, through constructive and destructive interference, can generate a steerable and localized “beam” or “spot” of microwave energy in one or more desired regions of the substrate surface. In some embodiments, microwave amplitude, phase, and direction can be rapidly varied electronically to generate a defined time-varying plasma intensity profile with a spatial resolution approximately (and/or of the order of) the wavelength of the microwave radiation.

Again, FIG. 1A illustrates a microwave beam 110 being directed towards a particular region of the substrate surface 120 due to its emission from PAMA 101. In FIG. 1A, the beam is emitted at a non-zero angle relative to the vertical, allowing it to be targeted appropriately. Additional examples are schematically illustrated in FIGS. 1B-1D. In FIG. 1B, the beam is directed towards a particular region by emitting it from the PAMA 101 with an off-center displacement, so that even if it is oriented vertically, it may be mapped to various regions of the substrate surface 120 as shown in FIG. 1B. FIG. 1C illustrates that, in some embodiments, a PAMA 101 may emit multiple microwave beams 110, 112, 114 simultaneously and, by doing so, simultaneously modify plasma density in the vicinity of multiple regions on the wafer surface 120. For example, a PAMA having 64 MW antennas might generate 8 or more individually controllable “beams.” FIG. 1D illustrates that, in some embodiments, a “spot” of microwave energy 116 may be generated—for example, by employing a multiply-stacked PAMA 102. PAMA 102 may be thought of as a 3-D phased-array, and the PAMAs 101 as 2-D phased arrays. As shown in FIG. 1D, the “spot” of microwave energy (and increased plasma density) is localized horizontally (similar to FIGS. 1A-1C), but also localized vertically relative to the wafer surface.

Because the targeted microwave radiation—as illustrated in FIGS. 1A-1D—increases the plasma density in the region of the substrate surface to which it is directed, this strategy serves as a mechanism for local adjustment and/or control of plasma density, and moreover, for the sought after local adjustment and/or control of any local reaction rates which depend on plasma density (and/or on the density of plasma-activated reactant species). As stated, these may be etch reactions, but they may also be film deposition reactions—because, e.g., ALD rates may also be influenced by local plasma density. Once again, this type of rate control does not require the etch or deposition process to be temperature-sensitive—only that it be plasma-activated—and so the utilization of phased-arrays of microwave antennas provides a powerful and general method of controlling local etch and/or deposition rates. Note that, depending on the embodiment, microwave radiation could serve as the main source of plasma energy, or it could serve as a supplemental directed energy source applied to modify the density of a plasma which is primarily maintained by another main source of energy (or simply another main source of microwave energy).

Also note that, depending on the embodiment, use of one or more PAMAs may allow one to divide the wafer surface up into specific computer addressable regions/locations. In so doing, local reaction rate adjustment can be programmatically assigned and controlled per specific region/location. If, for instance, it is desired that the local etch rate be adjusted in, e.g., Regions A, B, and C on the wafer surface, a computer program may be written to set the required phases and/or amplitudes and/or directions (and possibly frequencies and ranges of frequencies) of the microwave radiation emitted from a plurality of the microwave antennas of the PAMA such that a “beam” of microwave energy is directed to each of the A, B, and C Regions, with the proper intensity to alter the etch rate at each location by the desired amount. This plasma density modification in the vicinity of Regions A, B, and C, can be done sequentially, or (with a large enough PAMA) it can be done simultaneously with multiple beams (again by selection of the appropriate phases and/or amplitudes and/or directions emitted from the proper antennas of the array). Examples of directing beams of MW radiation emitted from a plurality of MW sources through the adjustment of relative phases and/or amplitudes and/or emission directionality from the MW sources—mechanistically, making use of constructive/destructive wave interference principles—may be found, for example, in “Phased Array Antennas”, R. C. Hansen, Wiley Series in Microwave and Optical Engineering, Kai Chang ed., 1998 and “Phased-Array Systems and Applications,” Nicholas Fourikis, Wiley Series in Microwave and Optical Engineering, Kai Chang ed., 1997, each of which is hereby incorporated by reference in its entirety for all purposes.

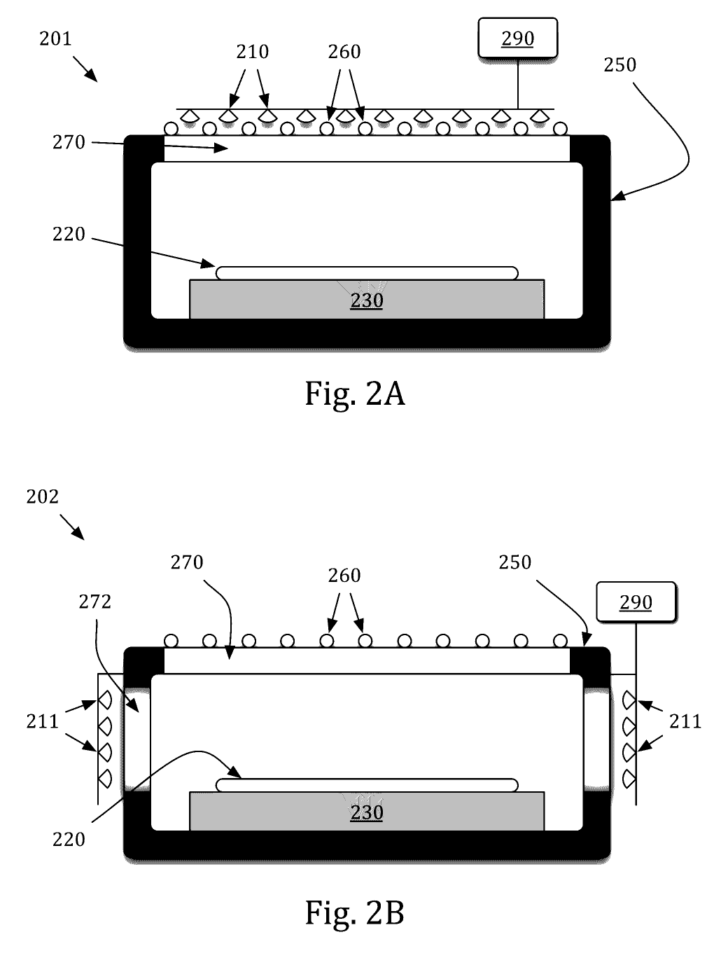

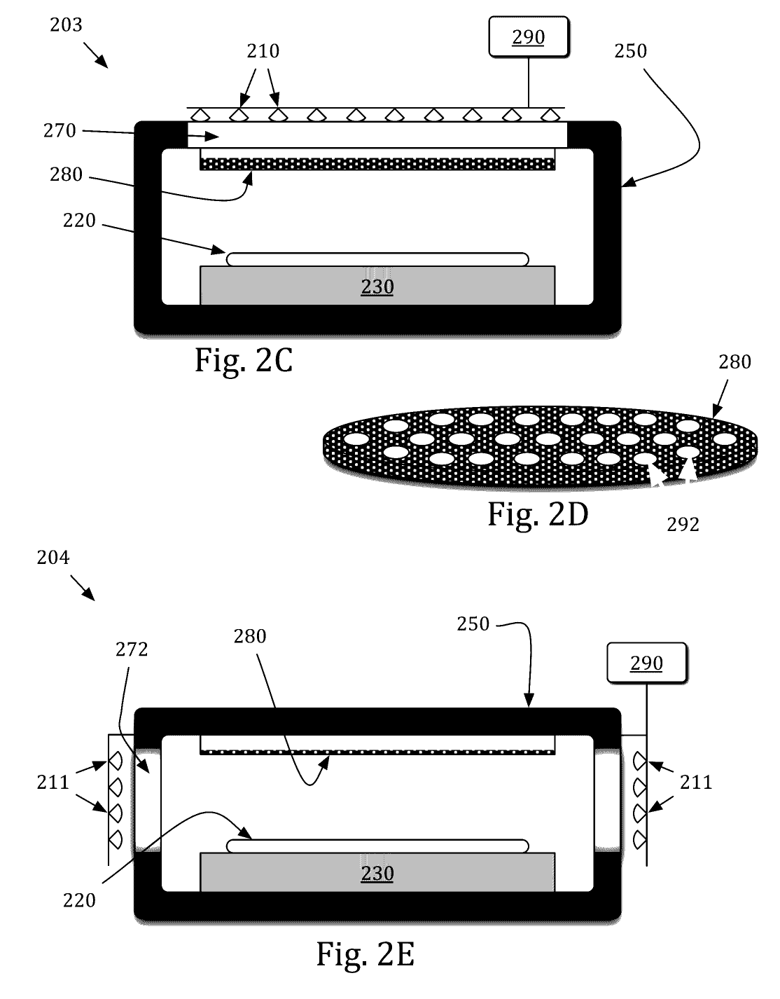

To achieve spatially-local reaction rate adjustment and/or control (etch rate and/or deposition rate, etc. as described), one or more PAMAs are strategically positioned relative to an appropriate substrate processing chamber. FIG. 2A schematically illustrates a substrate processing apparatus 201 with a PAMA 210 positioned relative to a semiconductor processing chamber 250. The PAMA 210 is depicted in FIG. 2A (and in FIGS. 2B-2E) as having a phase/amplitude control unit 290 connecting to all the antenna elements of the array so as to electrically control and vary their relative phases, amplitudes, and/or directions, as appropriate.

In this particular embodiment (FIG. 2A), the substrate processing apparatus 201 is an inductively coupled plasma (ICP) reactor having inductive coils 260. Located within the processing chamber is substrate 220 on substrate holder 230. Note that the individual antennas of the PAMA 210 are located and oriented such that they direct microwave radiation between inductive coils 260 (which, in general, would tend to absorb microwave radiation and thus would tend to shield the interior of chamber 250 from it). Both inductive coils 260 and phased-array 210 are located adjacent to a “window” 270 of processing chamber 250 which is (at least) to a certain extent transparent to RF and MW radiation (the notion being that, in general, the walls of processing chamber 250 would not be RF and MW transparent). The “window” 270 could be made of quartz or ceramic, for example, or other dielectric material, whereas in general the walls of the processing chamber are formed from a metal material.

An alternative embodiment of an ICP reactor apparatus 202 having a PAMA (or associated with a PAMA) is shown in FIG. 2B. In this embodiment, the PAMA 211 (note again the presence of amplitude/phase/direction control unit 290) is appropriately sized so that it wraps around the periphery of processing chamber 250 (shown cross-sectionally in FIG. 2B) and, accordingly, the (at least) partially MW transparent “window” 272 is located in the side/peripheral-walls of processing chamber 250. This design has the advantage that the inductive coils 260 (which are still located adjacent to the top window 270 of chamber 250) will not interfere with the transmission of microwave radiation from PAMA 210 into the processing chamber. However, there are other issues to consider with such designs as will be discussed in detail below.

FIGS. 2C-2E schematically illustrate the association (and/or integration) of a PAMA 210, 211 with a capacitively-coupled plasma (CCP) reactor. The apparatus design 203 shown in FIG. 2C is analogous to the ICP reactor 201 shown in FIG. 1A in the sense that PAMA 210 is located at the top of the processing chamber; however, instead of there being inductive coils for plasma generation (as in an ICP reactor (FIGS. 1A-1B)), there is a plate electrode 280 provided for plasma generation (through application of a voltage difference between plate electrode 280 and substrate holder/chuck 230). As the case with inductive coils 260 in FIG. 2A, the plate electrode 280 would tend to shield the interior of the processing chamber 250 from the microwave radiation emitted from PAMA 210. Accordingly, to deal with this issue, plate electrode 280 could be constructed with apertures 292, as shown in the perspective view shown in FIG. 2D, which would be roughly aligned with the locations of the individual antennas of array 210. Depending on the embodiment, the apertures may generally be round, or oval-shaped, or even slot-shaped, or a combination of the foregoing.

Likewise, FIG. 2E schematically illustrates the integration of side-mounted PAMA with a CCP reactor apparatus 204. Analogously to the side-mounted PAMA associated with the ICP reactor in FIG. 2B, the PAMA associated with the CCP reactor in FIG. 2E locates antennas around the periphery of the processing chamber 250—and, as in FIG. 2B, in the vicinity of a (at least) partially MW transparent “window” 272 in the side walls of processing chamber 250—which avoids the issue of interference by plate electrode 280. Note that by virtue of the sidewall locating of PAMA 211, the plate electrode 280 need not provide the apertures 292 shown in FIG. 2D. Furthermore, with PAMA 211 side-mounted around the periphery of reaction chamber 250, and with the plate electrode 280 located at the top of the reaction chamber but inside the top wall, the (at least partially) MW/RF-transparent window 270 may be eliminated (as shown in FIG. 2E). Other implications of this design are discussed below.

It is noted with respect to the processing apparatuses 201, 202, 203, and 204 shown in FIGS. 2A-2E (respectively), that the PAMAs 210 or 211 associated with each apparatus may be constructed in a manner that is integrated into the apparatus, or they may be separate components which are sized appropriate for being retrofitted to an existing apparatus design. Detailed descriptions of ICP reactors and also capacitively-coupled plasma (CCP) reactors are provided below which may be retrofitted with PAMAs for spatially-targeted reaction rate adjustment. Film deposition apparatuses (suitable for performing ALD processes) are also described below which may be suitably retrofitted with one or more PAMA devices.

Whether offered as an additional retrofit-able component, or as a fully integrated original component of a processing apparatus, the PAMA would be sized, and its antennas arranged appropriately, so as to effectively direct focused beam(s) of microwave radiation into the applicable processing chamber. Accordingly, an appropriate top-positioned PAMA may include 5-256 microwave antennas arranged substantially in a plane. The planar arrangement may include several substantially concentric circular groups of antennas. The outermost group may have a diameter of 200-400 mm, or more particularly, in certain such embodiments, 275-325 mm; there may be 3-24 substantially planar and substantially concentric circular groups of such antennas. In some embodiments, the mean spacing between adjacent antennas of the top-positioned/mounted PAMA may be 0.1-150 cm, or more particularly, 0.2-100 cm, or yet more particularly, 0.5-50 cm.

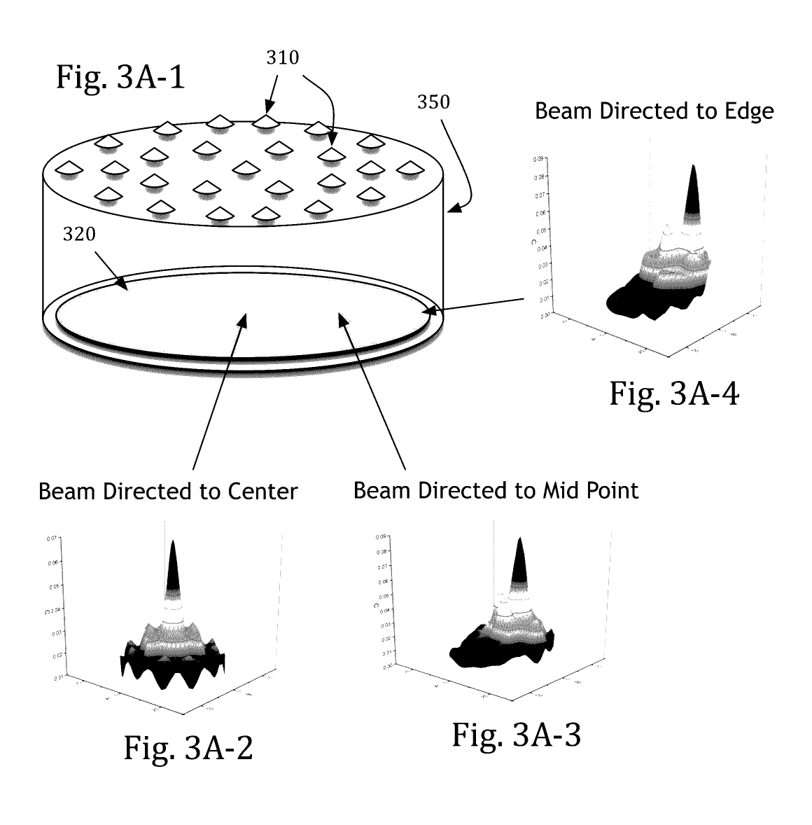

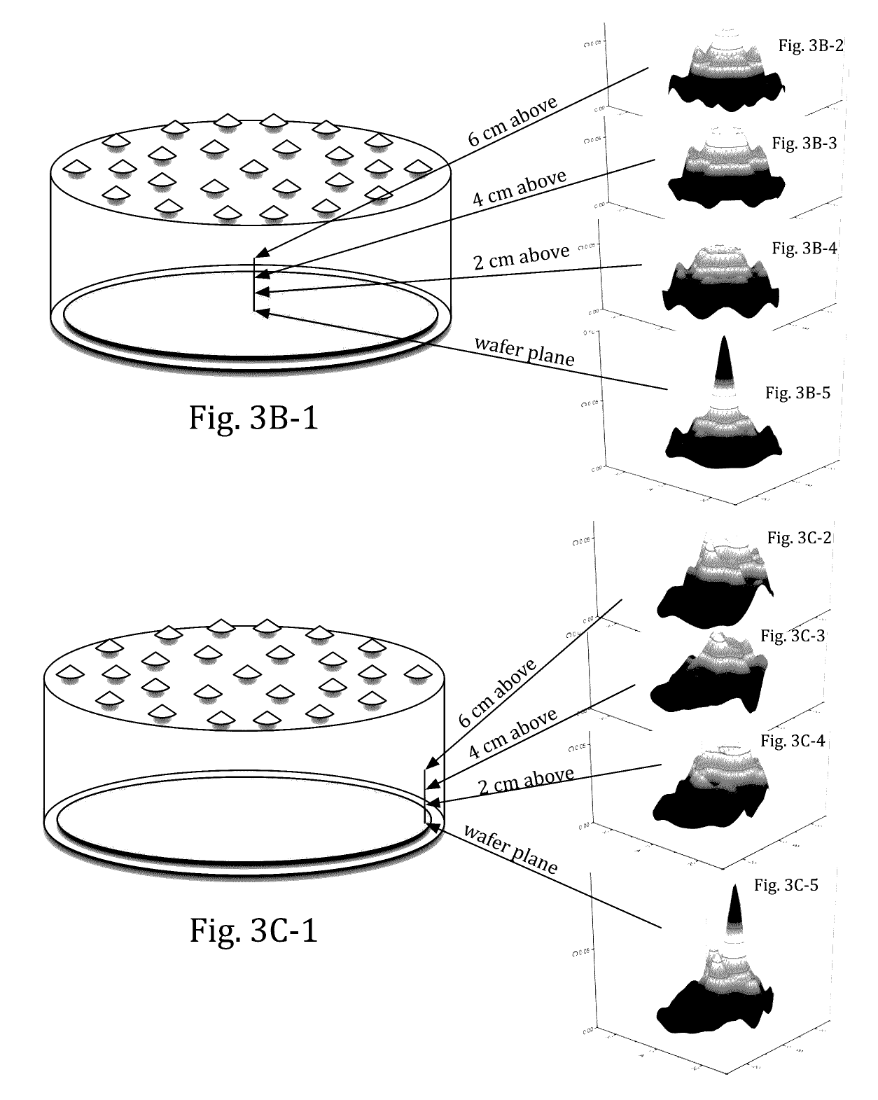

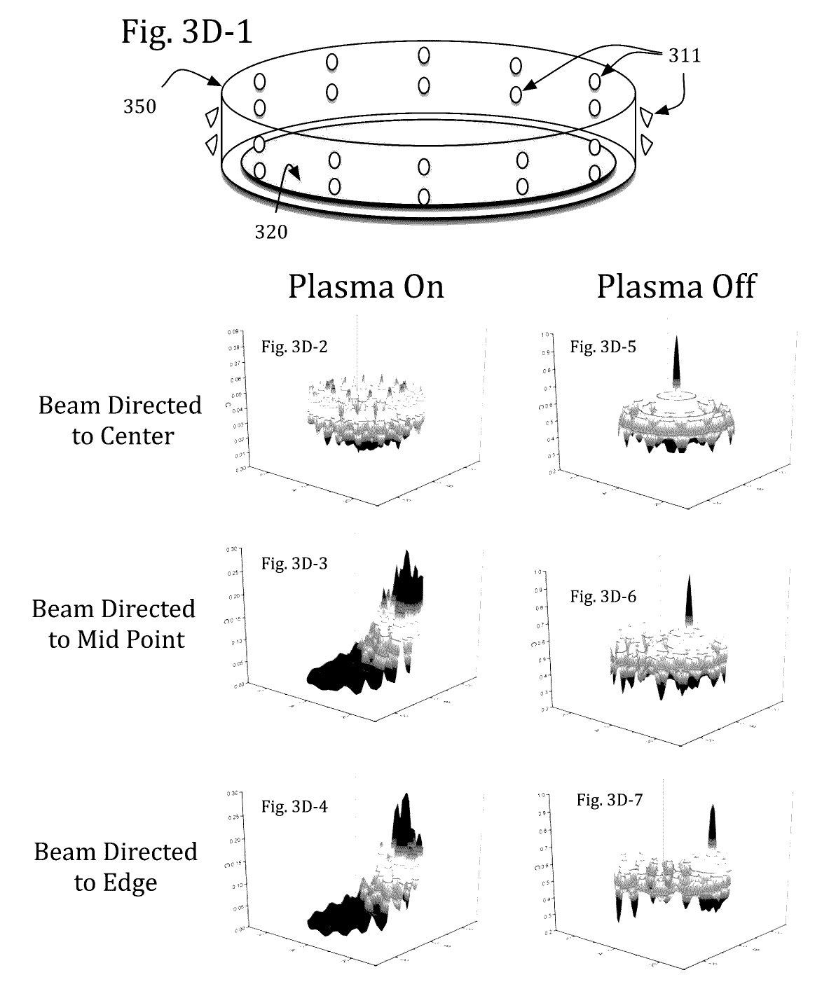

Likewise, an appropriate side/periphery-positioned PAMA may include 8-256 microwave antennas arranged substantially cylindrically with respect to each other as shown in FIGS. 2B and 2E (cross-sectionally) and in FIG. 3D-1 (discussed below). In some embodiments, the height of said cylindrical arrangement may be 5-500 mm, or more particularly 100-300 mm. In some embodiments, the diameter of said cylindrical arrangement may be 300-600 mm, or more particularly 350-450 mm. Mean spacings between adjacent antennas in a side/periphery-positioned PAMA may be 0.1-150 cm, or more particularly 0.1-15 cm. In some embodiments, the antennas may be arranged in a cylindrical stack of several groups of antennas, each group having a substantially circularly arrangement; there may be, for example, 2-7 of such groups (e.g., 4 groups in FIGS. 2B and 2E and 2 groups in FIG. 3D-1). In some embodiments, a substrate processing apparatus—for deposition, etching, or other processing operations—may include both top-mounted and side/periphery-mounted PAMAs which then may be used (cooperatively) in conjunction and/or unison to effect the desired level of plasma density modification. In some embodiments, with a sufficiently powerful PAMA or set of PAMAs, the PAMA(s) itself/themselves may be used as the main source of EM radiation to maintain and power the plasma, in addition to serving as a tool to generate direct-able beams of MW radiation for local plasma density modification. It is also noted that there is nothing in principle to prevent the forgoing PAMA-based surface reaction rate control techniques to be used in conjunction with a substrate temperature control array (such as individually controllable heat-generating resistive elements located within the substrate holder) to cooperatively (PAMA plus temp control array) work to adjust reaction rates on the substrate surface (though, to be effective, this would again require a temperature sensitive reactive process, etch, dep, or otherwise). Examples of such temperature control arrays may be found in U.S. Pat. No. 8,637,794, titled “Heating Plate with Planar Heating Zones for Semiconductor Processing,” filed Jan. 28, 2014, which is hereby incorporated by reference in its entirety for all purposes.

Simulation Results

FIGS. 3A-1 through 3D-7 provide simulation results illustrating the controlled focusing of microwave (MW) radiation onto or near a prototypical substrate surface as generated from a computer model of a phased-array consisting of 25 microwave antennas. The various results are generated by varying the relative phases and/or relative amplitudes of the microwave radiation emitted from the various antennas of the simulated PAMA.

As depicted in FIG. 3A-1, the first set of simulations model an apparatus configuration where the PAMA 310 is positioned above the reaction chamber 350, and the MW radiation is focused downwards towards a prototypical substrate 320. This configuration could thus correspond to the ICP etch chamber schematically illustrated in FIG. 2A or the CCP etch chamber in FIG. 2C. The results of three simulations are shown with the beam of MW radiation focused to three different spots on the substrate surface, as indicated in FIG. 3A-1: center, mid point, and edge in FIGS. 3A-2, 3A-3, and 3A-4, respectively. The results of the simulation show that the modeled PAMA does an excellent job of focusing a MW beam to each of the three designated spots on the substrate surface.

FIG. 3B-1 shows additional results for the same apparatus configuration (as in FIG. 3A-1). In this example, the MW beam is again focused to the center of the wafer (as was shown in FIG. 3A-2), but here the results shown in FIGS. 3B-2, 3B-3, and 3B-4 show the intensity of the MW radiation at various elevation slices above the plane of the wafer surface (as depicted in the figure) to be contrasted with the MW intensity at the plane of the wafer surface shown in FIG. 3B-5. These simulation results show that the MW radiation is not only horizontally localized across the substrate surface (as shown in FIG. 3A), but vertically localized as well. These simulations thus loosely correspond to what is depicted in FIG. 1D. FIG. 3C-1 through FIG. 3C-5 show similar results (MW intensity at various vertical slices contrasted with intensity in the plane of the wafer) for a beam of MW radiation directed towards the wafer edge, and again it is seen that significant vertical localization in MW intensity accompanies the horizontal localization.

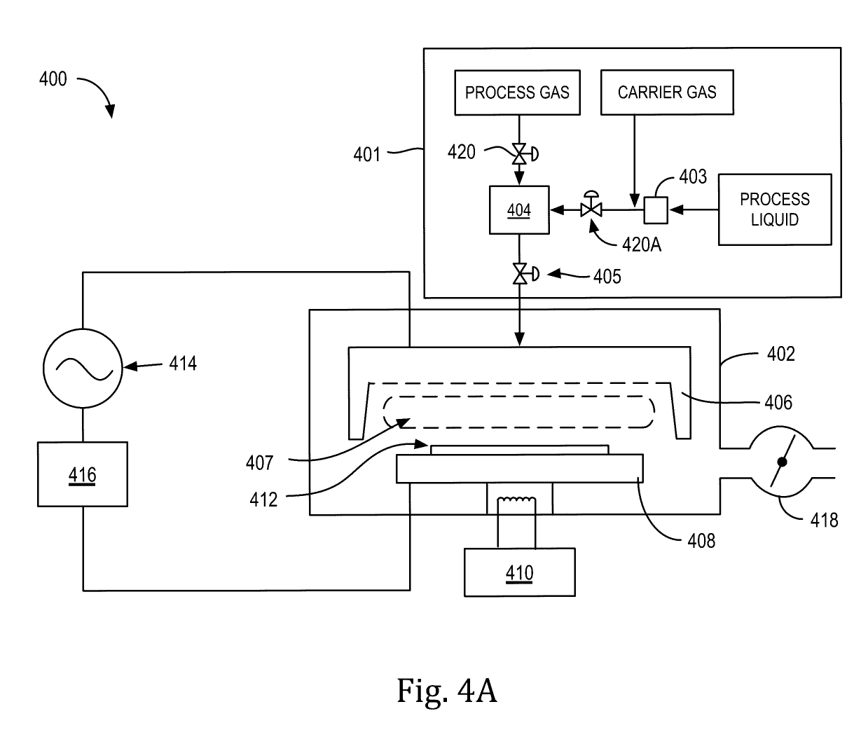

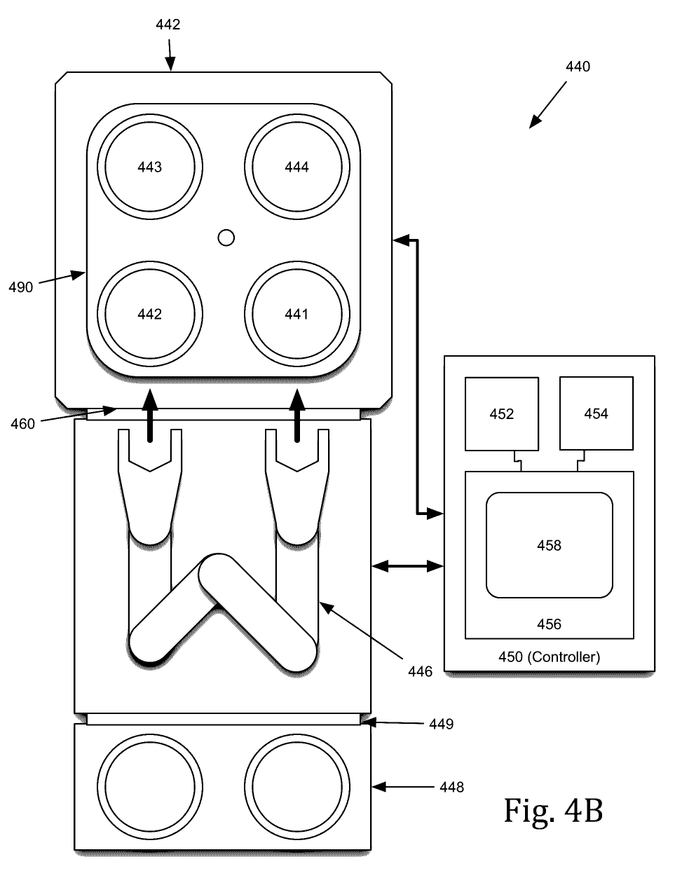

As depicted in FIG. 3D-1, the next group of simulations corresponds to an apparatus configuration where the PAMA 311 is positioned around the sides/periphery of the reaction chamber 350, and the MW radiation is focused inwards towards a prototypical substrate 320. This configuration could thus correspond to the ICP etch chamber schematically illustrated in FIG. 2B or to the CCP etch chamber in FIG. 2E. The results of three simulations are shown in FIGS. 3D-2, 3D-3, and 3D-4 with the MW beam directed to center, mid point, and edge, respectively, in the presence of an energized etch plasma within reaction chamber 350 (or 250 in FIG. 2B). Analogous results with the etch plasma turned off are shown in FIGS. 3D-5, 3D-6, and 3D-7 (again, MW beam directed to center, mid point, and edge, respectively). With the etch plasma on, the results show good horizontal localization of MW beam intensity at the mid point (FIG. 3D-3) and edge (FIG. 3D-4) of the substrate, but poor localization when the beam is directed to the center (FIG. 3D-2). This is a consequence of the substrate center being furthest from the antennas of the array. Note that this was not an issue with PAMA 310 located above the reaction chamber (see FIG. 3A-1, et seq.), since in that configuration one observes that the PAMA is located as near to the substrate center as it is to the edge and mid point regions of the substrate. However, FIGS. 3D-5, 3D-6, and 3D-7 (again, center, mid point, and edge, respectively) show that the problem of side/periphery-emitted MW radiation reaching the center of the substrate goes away if the plasma is turned off—the reason being that the energized plasma has ionized species which somewhat shield against transmission of MW radiation, whereas the un-energized plasma does not. This suggests that cycling the plasma between energized and un-energized states may allow for the pulsed application of targeted MW radiation with this PAMA configuration, even to the center of the substrate's surface (although it may be that, in some embodiments, reaction/etch rate adjustment/enhancement is most important near the substrate mid point and edge regions, anyway).

### Plasma-Enhanced Deposition Processes and Associated Apparatuses

Described above are various techniques for adjusting and/or controlling local temperature or local plasma density near a semiconductor substrate surface in a processing operation. These techniques may be applied in the context of etch or deposition operations, and in particular, on the deposition side, in plasma-enhanced chemical vapor deposition (PECVD) processes, as well as atomic layer deposition (ALD) processes. Accordingly, provided here is an overview of these deposition operations and associated deposition apparatuses. Further below is an overview of the apparatuses that may be used for various substrate etching operations and which may also benefit from using a phased-array of microwave antennas to locally adjust plasma density near the substrate surface.

Overview of Deposition Processes

Many challenges may be associated with the implementation of film deposition processes on semiconductor wafers, many stemming from the fact that it is desired that these processes exhibit good across-wafer uniformity, uniformity from deposition cycle-to-cycle on a single wafer, as well as good uniformity across a batch of wafers. Additionally it may be desired to intentionally deposit a specific non-uniform film thickness, to compensate for some upstream or downstream non-uniformity. On top of this, processing throughput requirements often demand rapid deposition cycle times, and this may place high demands on the associated physical hardware as well as the process design requirements. As described above, plasma uniformity is often an important issue, and the striking of the plasma during film deposition may make a uniform across-wafer plasma density difficult to achieve. Such issues may be benefited by the techniques for achieving greater plasma density control via phased-array antennas as described above.

As described in further detail below, a basic ALD cycle for depositing a single layer of material on a substrate in a processing chamber may include: (i) adsorbing a film precursor on a substrate such that it forms an adsorption-limited layer, (ii) removing (at least some, when present) unadsorbed (including desorbed) film precursor from the vicinity of the process station holding the substrate, and (iii) after removing unadsorbed film precursor, reacting the adsorbed film precursor—e.g, by igniting a plasma in the vicinity of said process station—to form a layer of film on the substrate. (“Unadsorbed” film precursor, as used herein, is defined to include desorbed film precursor.) Oftentimes, an ALD cycle additionally involves an operation (iv) of, after the reaction of adsorbed film precursor, removing desorbed film precursor and/or film precursor reaction by-product from the vicinity of said process station holding the substrate having been deposited upon. The removing in operations (ii) and (iv) may be done via purging the vicinity of the substrate, evacuating by pumping down to a base pressure (“pump-to-base”), etc. The plasma used to activate the surface reaction in operation (iii) is typically supported by a plasma feed gas which, for example, may be flowed into the reaction chamber through one or more showerheads (described in greater detail below). In some embodiments, the plasma feed gas may be used to purge the chamber in order to effectuate the removal in operations (ii) and (iv).

However (as stated), the across-wafer uniformity of films deposited via PECVD processes, may also benefit from local plasma density control, such as via the employment of phased-arrays of microwave antennas as described above. Traditional PECVD processes bear some general similarity to ALD processes—e.g., they both involve the introduction of gas-phase film precursor into a process chamber followed by subsequent plasma-activation of these precursors to form a layer of film on the substrate. However, in PECVD, the film-forming reactions take place while the film precursor is still in the gas-phase (or at least to a large extent) resulting in the film material being formed faster in larger quantities and thereafter depositing itself down onto the wafer surface. In other words, in contrast to ALD processes, the film-forming reactions taking place in PECVD processes are generally not surface-mediated and adsorption-limited, and thus significantly more than an adsorption-limited layer of film material is deposited in each PECVD cycle. In some embodiments, this—the fact that PECVD is less gradual—makes PECVD generally less uniform than ALD, and thus more apt to derive a significant benefit from the local plasma density control techniques and hardware disclosed herein.

Film Deposition Apparatuses

Operations for depositing films on semiconductor substrates may generally be performed in a substrate processing apparatus like that shown in FIG. 4A. The apparatus 400 of FIG. 4A, which will be described in greater detail below, has a single processing chamber 402 with a single substrate holder 408 in an interior volume which may be maintained under vacuum by vacuum pump 418. Also fluidically coupled to the chamber for the delivery of (for example) film precursors, carrier and/or purge and/or process gases, secondary reactants, etc. is gas delivery system 401 and showerhead 406. Equipment for generating a plasma within the processing chamber is also shown in FIG. 4A and will be descried in further detail below. In any event, as it is described in detail below, the apparatus schematically illustrated in FIG. 4A provides the basic equipment for performing film deposition operations on semiconductor substrates such as those operations employed in plasma-enhanced chemical vapor deposition (PECVD) processes as well as those employed in atomic layer deposition (ALD) processes.

While in some circumstances a substrate processing apparatus like that of FIG. 4A may be sufficient, when time-consuming film deposition operations are involved, it may be advantageous to increase substrate processing throughput by performing multiple deposition operations in parallel on multiple semiconductor substrates simultaneously. For this purpose, a multi-station substrate processing apparatus may be employed like that schematically illustrated in FIG. 4B. The substrate processing apparatus 440 of FIG. 4B employs a single substrate processing chamber 445 (as processing apparatus 400 in FIG. 4A is depicted as employing a single processing chamber 402), however, within the single interior volume defined by the walls of the processing chamber, are multiple substrate process stations, each of which may be used to perform processing operations on a substrate held in a wafer holder associated with that process station. In this particular embodiment, the multi-station substrate processing apparatus 440 is shown having 4 process stations 441, 442, 443, and 444. The apparatus also employs a substrate loading device, in this case substrate handler robot 446, for loading substrates at process stations 441 and 442, and a substrate transferring device, in this case substrate carousel 490, for transferring substrates between the various process stations 441, 442, 443, and 444. Note that, depending on the embodiment and as mentioned above, each process station may be associated with its own phased-array of microwave antennas—i.e., an array specific to it, and thus, e.g., a 4-station chamber would have 4 phased-arrays—or, in some embodiments, a single phased-array might provide one or more beams of steerable microwave radiation which can be used to affect plasma density at multiple process stations—e.g., a 4-station chamber might have a single phased-array of microwave antennas which adjusts plasma density at all 4 process stations. Other similar multi-station processing apparatuses may have more or fewer processing stations depending on the embodiment and, for instance, the desired level of parallel wafer processing, size/space constraints, cost constraints, etc. Also shown in FIG. 4B is a controller 450 (to be described in greater detail below) which assists the goal of performing efficient substrate deposition operations such as in, for example, ALD operations.

Note that various efficiencies—with respect to both equipment cost and operational expense—may be achieved through the use of a multi-station processing apparatus like that shown in FIG. 4B. For instance, a single vacuum pump (not shown in FIG. 4B, but e.g. 418 in FIG. 4A) may be used to create a single high-vacuum environment for all 4 process stations, and said pump may also be used to evacuate spent process gases, etc. with respect to all 4 process stations. Depending on the embodiment, each process station typically has its own dedicated showerhead for gas delivery (see, e.g., 406 in FIG. 4A), but some components of the gas delivery system (e.g., 401 in FIG. 4A) which supplies gas to the showerheads may be shared. Likewise, certain elements of the plasma generator equipment may be shared amongst process stations (e.g., power supplies), although depending on the embodiment, certain aspects may be process station-specific (for example, if showerheads are used to apply plasma-generating electrical potentials—see the additional discussion of FIG. 4A below). Once again, however, it is to be understood that such efficiencies may also be achieved to a greater or lesser extent by using more or fewer numbers of process stations per processing chamber such as 2, 3, 5, 6, 7, 8, 9, 10, 11, 12, 13, 14, 15, or 16, or more process stations per reaction chamber.

Another advantage associated with employing multiple process stations in a single processing chamber is that such designs typically allow for the use of higher-power plasmas than would generally be feasible in single process station chamber. This is due to the fact that a multi-station chamber is generally volumetrically larger than a single station chamber, and the larger chamber volume allows for the use of larger voltages for plasma generation without causing electrical arcing to the chamber walls; meaning that larger plasma powers can be safely used. The higher plasma powers are beneficial because, for example, in the case of dielectric film deposition, use of a higher-powered plasma results in a deposited dielectric film with a correspondingly higher-density, which is often a desirable property.

While using larger processing chambers with multiple process stations may provide the aforementioned benefits, there are, on the other hand, certain advantages which would generally be associated with employing a smaller single-station processing chamber. One of these is the rapid cycling of chamber volumes—i.e., the ability to rapidly introduce and remove reactants, reaction by-products, etc. Such rapid cycling may be particular important in ALD processes where many deposition cycles are required to deposit a film of appreciable thickness, and thus time-spent cycling chamber volumes may be quite significant. Thus, to combine the benefits of larger-volume multi-process station chambers with those benefits typically associated with smaller-volume single-process station chambers, a multi-station/chamber processing apparatus may “simulate” a small volume chamber at each process station by flowing curtains of gas between the various process stations, thereby volumetrically isolating them from each other during film deposition operations. For instance, during a deposition operations, such a “curtain gas” may be flowed between the process stations to prevent intermixing of reactants, plasma feed gases, etc. while not interfering with (at least not to an unworkable extent) the reactive film-deposition processes occurring at each process station. While this may “simulate” a smaller volume for the purposes of reactant flow and by-product purge, the advantages of a larger chamber volume remain intact with respect to high-plasma power and scaling of certain component costs.

Moreover, in addition to the foregoing benefits, volumetric isolation of process stations via curtain gas flow may allow the sequence of operations making up a deposition cycle to be staggered between process stations. Various benefits associated with such staggered cycling with respect to ALD processes, for example, are described in detail in U.S. patent application Ser. No. 14/133,246 (Atty. Dock. No. LAMRP059US), filed Dec. 18, 2013, now U.S. Pat. No. 8,940,646, titled “SEQUENTIAL PRECURSOR DOSING IN AN ALD MULTI-STATION/BATCH REACTOR,” hereby incorporated by reference in its entirety for all purposes.

It is noted, however, that in order for the foregoing benefits to be achieved—with respect to ALD or PECVD operations—it is not necessarily the case that the various process stations are perfectly volumetrically isolated from one another by the curtain gas flow. In general, one would expect this not to be the case. Thus, in the context of this disclosure, “volumetrically isolating” one process station from another via curtain gas flow is to be interpreted to mean that the curtain gas flow between process stations works to significantly reduce the mixing of gases between process stations that what would occur if no such curtain gas were employed. This is to be contrasted with the “complete” or “perfect” volumetric isolation that would exist if each process station resided in its own separate process chamber; volumetrically isolating with a curtain gas does not imply or require such perfect/complete separation/isolation.

It is also noted that, in plasma-based deposition operations, the curtain gas may be viewed conceptually as distinct from the plasma feed gas, the latter being used to support the plasma which is used to activate the reaction which causes film deposition. Note that, in some embodiments, the plasma feed gas is also used as a purge gas for removing unadsorbed film precursor (reactant) from the vicinity of the different process stations, when appropriate. Thus, while the curtain gas could (and typically would) be flowed continuously into the processing station during all the stages of a deposition cycle, the plasma feed gas would typically only be flowed to the processing chamber—and, more specifically, to the process stations—during the plasma activation (and purge operations if also used as a purge gas) while they are carried out at the specific process stations.

In some embodiments, multi-station film deposition apparatuses may employ chandelier-type showerheads, one associated with each process station. Such chandelier showerheads may generally include a head portion and stem portion, the bottom surface of the head portion providing apertures for flowing film precursor, plasma feed gas, and possibly a distinct purge gas into the processing chamber in the vicinity of each process station. The stem portion of the showerhead is present to support/hang the head portion above each process station within the processing chamber, and also to provide a fluidic path/connection for flowing film precursor (and/or other reactants), plasma feed gas, etc. to the apertures in the head portion. Generally, it is seen that chandelier-type showerhead designs allow for a good spatially uniform distribution of film precursor flow relative to the substrate surface, and improved in comparison to what would otherwise be achieved with just a few nozzles serving as point sources of flow.

In addition, such showerheads may also play a role in generating (and maintaining) the plasma at each process station which is used to activate the deposition reaction (whether in ALD or PECVD operations). In particular, upon application of a suitable electrical potential, each chandelier showerhead may serve as one of the two electrodes for plasma generation, the other electrode being the substrate holder (e.g., pedestal) between which the electrical potential is applied. The chandelier design allows positioning of the showerhead close to the substrate surface, which thereby allows for efficient plasma generation very close to the substrate as well as to provide a spatially uniform distribution of film precursor (reactant) close to the substrate. Note also that plasma generation in this manner (via chandelier—type showerhead) may provide a greater spatial separation between plasma and the grounded chamber walls which, again, allows for the use of higher powered plasmas (versus using a showerhead mounted flush with the chamber top wall, for example). In addition, as mentioned above, if the plasma feed gas is also used as a purge gas, then its introduction in the vicinity of the substrate allows for an efficient and effective purge of unadsorbed film precursor and/or reactant by-product.

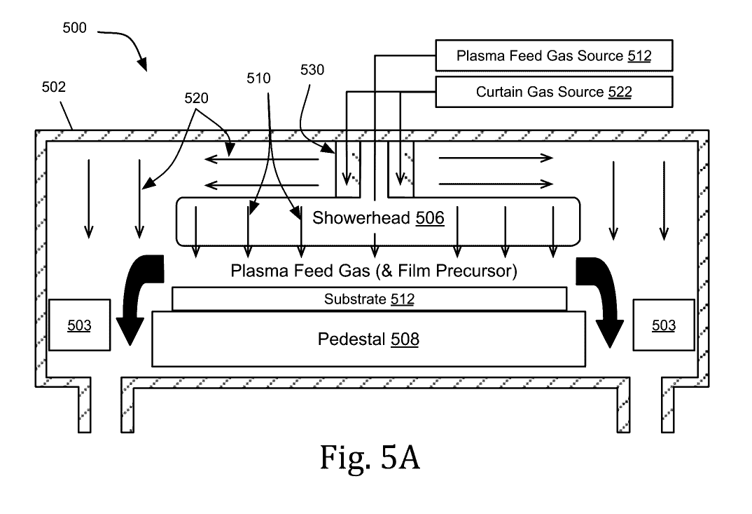

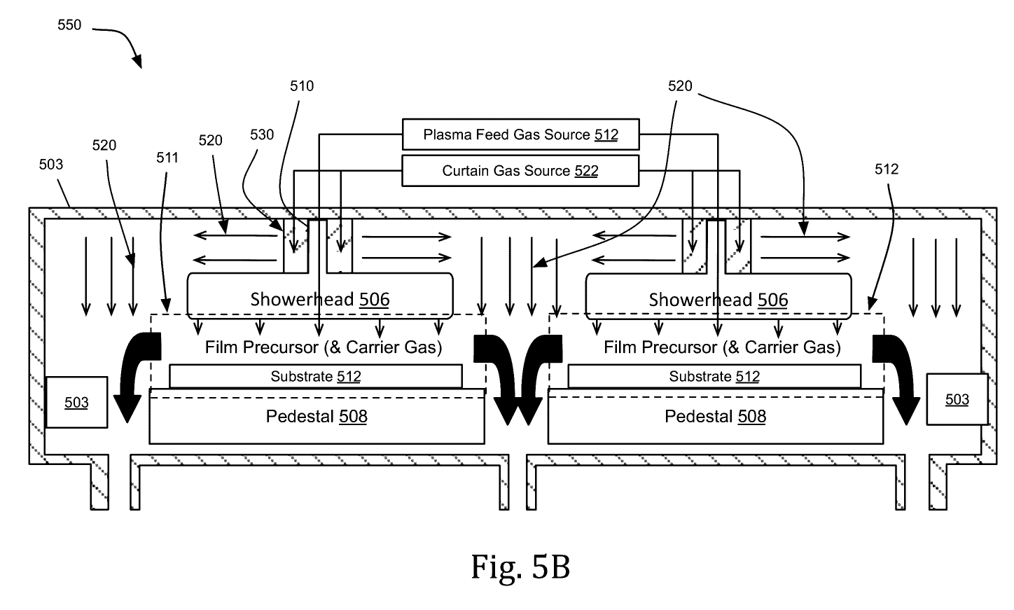

Also, while use of a chandelier-type showerhead allows the plasma feed gas to be introduced close to the substrate surface, the curtain gas may be introduced into the processing chamber from entry points behind the head portions of each of the chandelier showerheads, and in particular, in some embodiments, through apertures in the showerhead collars which surround the stem portions of the showerheads. Moreover, in certain such embodiments, the curtain gas may be flowed from these apertures in directions substantially parallel to the plane of the substrate and/or the bottom surfaces of the head portions, and thus, generally initially in directions perpendicular to the flow emanating from the bottom surface of the head of the showerhead. This flow of curtain gas may continue laterally until the curtain gas reaches the end of the backside of the showerhead (top surface of the head portion of the showerhead) at which point the curtain gas flow may turn downward, now parallel to the flow of plasma feed and/or purge gas from the head of the showerhead. Such a flow pattern is illustrated with respect to a single process chamber in FIG. 5A—see, processing chamber 502, showerhead 506, showerhead collar 530; and curtain gas and plasma feed (and reactant precursor) flow paths 510 and 520, respectively. In the configuration shown in FIG. 5A, consistent with the foregoing description, plasma feed gas from plasma feed gas source 512 is flowed into chamber 502 through the bottom surface of the head portion of showerhead 506, while curtain gas from curtain gas source 522 is flowed into chamber 502 through apertures in the showerhead collar 530 which surrounds the stem portion of showerhead 506. Thus, the curtain gas here (note the descriptive phrase “curtain gas” is retained, even in the single station context) is introduced into the processing chamber 502 near to the center axis of the backside of the showerhead 506 and introduced with a flow substantially parallel to the plane of the substrate 512 held on pedestal 508 (and substantially parallel to the bottom surface of the head portion of the showerhead 506). The curtain gas so introduced then proceeds to flow around the showerhead and down the chamber sidewalls before exiting the chamber in the vicinity of cross-plates 503 (as schematically illustrated by the arrows in FIG. 5A).

Volumetric isolation between process stations via curtain gas flow is illustrated in FIG. 5B which shows a pair of process stations 511 and 512 (see dashed lines in FIG. 5B) within a multi-station processing chamber 503 of a processing apparatus 550. As illustrated in the figure by arrows indicative of the direction of gas flow, in addition to the curtain gas flow pattern shown in FIG. 5A (in the context of a single station), here the curtain gas 520 additionally flows between the process stations 511 and 512 volumetrically isolating them from one another. Note that this view shows a pair of process stations in cross section, so the view could represent a 2-station processing chamber embodiment, or it could represent a cross-sectional view of a 4-station processing chamber embodiment, such as that schematically illustrated in FIG. 4B. In any event, each process station of the pair shown are analogous to the single process station shown in FIG. 5A, and thus the description accompanying FIG. 5A (as well as reference numbering), applies to FIG. 5B as well where appropriate, the most important difference being that in FIG. 5B there are a pair of process stations 511 and 512, and the pair are volumetrically isolated/separated from each other by the flow of curtain gas 520.

Various further aspects of the single process station deposition apparatus shown in FIG. 4A are now described; it is apparent that many of these further aspects now described also apply within the context of a multi-station/chamber deposition apparatus. As shown in the figure, process station 400 fluidly communicates with reactant delivery system 401 for delivering process gases to a distribution showerhead 406. Reactant delivery system 401 includes a mixing vessel 404 for blending and/or conditioning process gases for delivery to showerhead 406. One or more mixing vessel inlet valves 420 may control introduction of process gases to mixing vessel 404. Some reactants may be stored in liquid form prior to vaporization and subsequent delivery to the process chamber 402. The embodiment of FIG. 4A includes a vaporization point 403 for vaporizing liquid reactant to be supplied to mixing vessel 404. In some embodiments, vaporization point 403 may be a heated liquid injection module. In some embodiments, vaporization point 403 may be a heated vaporizer. The saturated reactant vapor produced from such modules/vaporizers may condense in downstream delivery piping when adequate controls are not in place (e.g., when no helium is used in vaporizing/atomizing the liquid reactant). Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 403 may be heat treated. In some examples, mixing vessel 404 may also be heat treated. In one non-limiting example, piping downstream of vaporization point 403 has an increasing temperature profile extending from approximately 100° C. to approximately 150° C. at mixing vessel 404.

In some embodiments the vaporization point 403 may be a heated liquid injection module (“liquid injector” for short). Such a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 803. In one scenario, a liquid injector may be mounted directly to mixing vessel 804. In another scenario, a liquid injector may be mounted directly to showerhead 106.

In some embodiments, a liquid flow controller (LFC) upstream of vaporization point 403 may be provided for controlling a mass flow of liquid for vaporization and delivery to processing chamber 402. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 406 distributes process gases and/or reactants (e.g., film precursors) toward substrate 412 at the process station, the flow of which is controlled by one or more valves upstream from the showerhead (e.g., valves 420, 420A, 405). In the embodiment shown in FIG. 4A, substrate 412 is located beneath showerhead 406, and is shown resting on a pedestal 408. It will be appreciated that showerhead 406 may have any suitable shape, and may have any suitable number and arrangement of ports for distributing processes gases to substrate 412.

In some embodiments, a microvolume 407 is located beneath showerhead 406. Performing an ALD process in a microvolume in the process station near the substrate rather than in the entire volume of a processing chamber may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters.

In some embodiments, pedestal 408 may be raised or lowered to expose substrate 412 to microvolume 407 and/or to vary a volume of microvolume 407. For example, in a substrate transfer phase, pedestal 408 may be lowered to allow substrate 412 to be loaded onto pedestal 408. During a deposition on substrate process phase, pedestal 408 may be raised to position substrate 412 within microvolume 407. In some embodiments, microvolume 407 may completely enclose substrate 412 as well as a portion of pedestal 408 to create a region of high flow impedance during a deposition process.

Optionally, pedestal 408 may be lowered and/or raised during portions the deposition process to modulate process pressure, reactant concentration, etc. within microvolume 407. In one scenario where processing chamber body 402 remains at a base pressure during the process, lowering pedestal 408 may allow microvolume 407 to be evacuated. Example ratios of microvolume to process chamber volume include, but are not limited to, volume ratios between 1:500 and 1:10. It will be appreciated that, in some embodiments, pedestal height may be adjusted programmatically by a suitable system controller. In another scenario, adjusting a height of pedestal 408 may allow a plasma density to be varied during plasma activation and/or treatment cycles included, for example, in an ALD or CVD process. At the conclusion of a deposition process phase, pedestal 408 may be lowered during another substrate transfer phase to allow removal of substrate 412 from pedestal 408.

While the example microvolume variations described herein refer to a height-adjustable pedestal, it will be appreciated that, in some embodiments, a position of showerhead 406 may be adjusted relative to pedestal 408 to vary a volume of microvolume 407. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable system controllers having machine-readable instructions for performing all or a subset of the foregoing operations.

Further, as shown in FIG. 4A, showerhead 406 and pedestal 408 electrically communicate with RF power supply 414 and matching network 416 for powering a plasma. In some embodiments, the plasma energy may be controlled (e.g., via a system controller having appropriate machine-readable instructions) by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Examples of suitable powers are included above. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy (OES) sensors. In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma activation phase may be included in a corresponding plasma activation recipe phase of a process recipe. In some cases, process recipe phases may be sequentially arranged, so that all instructions for a process phase are executed concurrently with that process phase. In some embodiments, instructions for setting one or more plasma parameters may be included in a recipe phase preceding a plasma process phase. For example, a first recipe phase may include instructions for setting a flow rate of an inert (e.g., helium) and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations described herein, much shorter plasma strikes may be applied during a processing cycle. These may be on the order of 50 milliseconds to 1 second, with 0.25 seconds being a specific example. Such short RF plasma strikes require quick stabilization of the plasma. To accomplish this, the plasma generator may be configured such that the impedance match is preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with ALD cycles.

In some embodiments, pedestal 408 may be temperature controlled via heater 410. Further, in some embodiments, pressure control for processing apparatus 400 may be provided by one or more valve-operated vacuum sources such as butterfly valve 418. As shown in the embodiment of FIG. 4, butterfly valve 418 throttles a vacuum provided by a downstream vacuum pump (not shown). However, in some embodiments, pressure control of processing apparatus 400 may also be adjusted by varying a flow rate of one or more gases introduced to processing chamber 402. In some embodiments, the one or more valve-operated vacuum sources—such as butterfly valve 418—may be used for removing film precursor from the volumes surrounding the process stations during the appropriate ALD operational phases.

Returning now to FIG. 4B, as described above, one or more process stations may be included in a multi-station substrate processing tool. FIG. 4B schematically illustrates an example of a multi-station processing tool 440 which includes a plurality of process stations 441, 442, 443, 444 in a common low-pressure processing chamber 445. By maintaining each station in a low-pressure environment, defects caused by vacuum breaks between film deposition processes may be avoided.

As shown in FIG. 4B, the multi-station processing tool 440 has a substrate loading port 460, and a substrate handler robot 446 configured to move substrates from a cassette loaded from a pod 448, through atmospheric port 449, into the processing chamber 445, and finally onto a process station. Specifically, in this case, the substrate handler robot 446 loads substrates at process stations 441 and 442, and a substrate transferring device, in this case substrate carousel 490, transfers substrates between the various process stations 441, 442, 443, and 444. In the embodiment shown in FIG. 4B, the substrate loading device is depicted as substrate handler robot 446 having 2 arms for substrate manipulation, and so, as depicted, it could load substrates at both stations 441 and 442 (perhaps simultaneously, or perhaps sequentially). Then, after loading at stations 441 and 442, the substrate transferring device, carousel 490 depicted in FIG. 4B, can do a 180 degree rotation (about its central axis, which is substantially perpendicular to the plane of the substrates (coming out of the page), and substantially equidistant between the substrates) to transfer the two substrates from stations 441 and 442 to stations 443 and 444. At this point, handler robot 446 can load 2 new substrates at stations 441 and 442, completing the loading process. To unload, these steps can be reversed, except that if multiple sets of 4 wafers are to be processed, each unloading of 2 substrates by handler robot 446 would be accompanied by the loading of 2 new substrates prior to rotating the transferring carousel 490 by 180 degrees. Analogously, a one-armed handler robot configured to place substrates at just 1 station, say 441, would be used in a 4 step load process accompanied by 4 rotations of carousel 490 by 90 degrees to load substrates at all 4 stations.

The depicted processing chamber 445 shown in FIG. 4B provides four process stations, 441, 442, 443, and 444. Each station has a heated pedestal (shown at 408 for the process station shown in FIG. 4A) and gas line inlets. It will be appreciated that in some embodiments, each process station may have different or multiple purposes. For example, in some embodiments, a process station may be switchable between an ALD process mode and a CVD/PECVD process mode. Additionally or alternatively, in some embodiments, processing chamber 445 may include one or more matched pairs of ALD/CVD/PECVD process stations. While the depicted processing chamber comprises 4 process stations, it will be understood that a processing chamber according to the present disclosure may have any suitable number of stations. For example, in some embodiments, a processing chamber may have 1, or 2, or 3, or 4, or 5, or 6, or 7, or 8, or 9, or 10, or 11, or 12, or 13, or 14, or 15, or 16, or more process stations (or a set of embodiments may be described as having a number of process stations per reaction chamber within a range defined by any pair of the foregoing values, such as having 2 to 6 process stations per reaction chamber, or 4 to 8 process stations per reaction chamber, or 8 to 16 process stations per reaction chamber, etc.).

As indicated above, FIG. 4B depicts an embodiment of a substrate transferring device 490 for transferring substrates between process stations 441, 442, 443, and 444 within processing chamber 445. It will be appreciated that any suitable substrate transferring device may be employed. Non-limiting examples include wafer carousels and substrate handler robots.

### Description of Etch Processing Apparatuses

A phased-array of microwave antennas and the microwave directing and focusing techniques disclosed herein may also be employed in an etch process and thus in an etch processing apparatus. A suitable apparatus for accomplishing semiconductor substrate etching operations may include one or more process stations/modules included in a multi-station substrate processing tool (as described below), and a controller (as described below) having (or having access to) machine-readable instructions for controlling process operations of the apparatus in accordance with the techniques and operations described herein.

Thus, as described more specifically in the context of the various capacitively coupled plasma (CCP) and inductively coupled plasma (ICP) reactors described below, an appropriate substrate processing apparatus may generally include a processing chamber, a plasma generator, one or more gas flow inlets configured for flowing gases into the processing chamber, a vacuum pump, a valve-controlled conduit to the vacuum pump, a phased-array of microwave antennas (PAMA), and a controller for controlling the operations of these components. In some embodiments, such an apparatus may further include an optical detector for measuring emission intensities of plasmas formed in its processing chamber, and the processing module embodied by the foregoing apparatus may have access to a metrology tool for measuring an etch profile of a feature etched on a semiconductor substrate using this apparatus. The following descriptions illustrate suitable etch chambers in greater detail.

Capacitively Coupled Plasma Reactors for Use in Etch Operations

Capacitively coupled plasma (CCP) reactors are described in U.S. Pat. No. 8,552,334, filed Feb. 9, 2009 as U.S. patent application Ser. No. 12/367,754, and titled “ADJUSTABLE GAP CAPACITIVELY COUPLED RF PLASMA REACTOR INCLUDING LATERAL BELLOWS AND NON-CONTACT PARTICLE SEAL,” and in U.S. patent application Ser. No. 14/539,121, filed Nov. 12, 2014, and titled “ADJUSTMENT OF VUV EMISSION OF A PLASMA VIA COLLISIONAL RESONANT ENERGY TRANSFER TO AN ENERGY ABSORBER GAS,” each of which is hereby incorporated by reference in its entirety for all purposes.

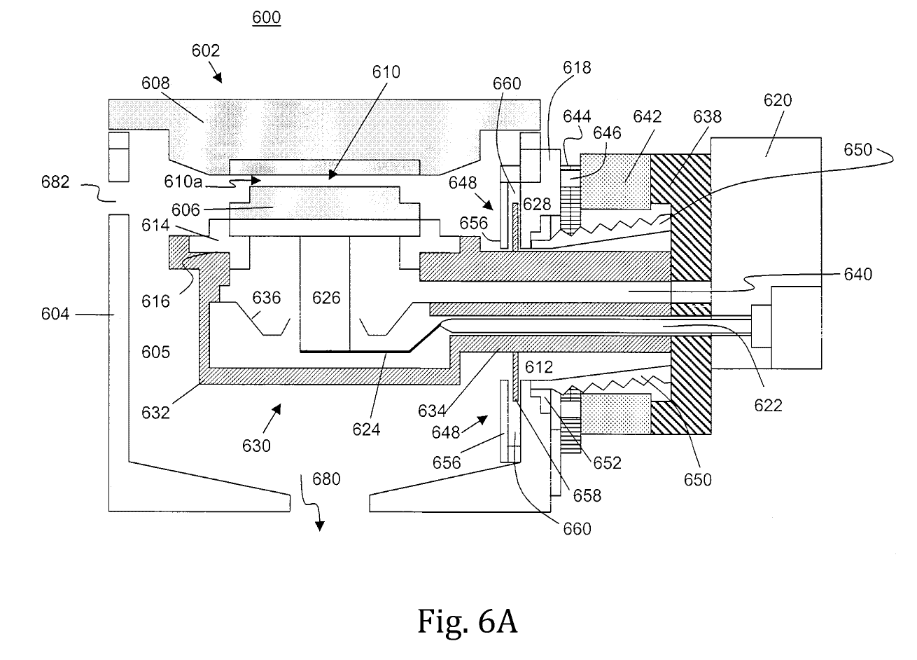

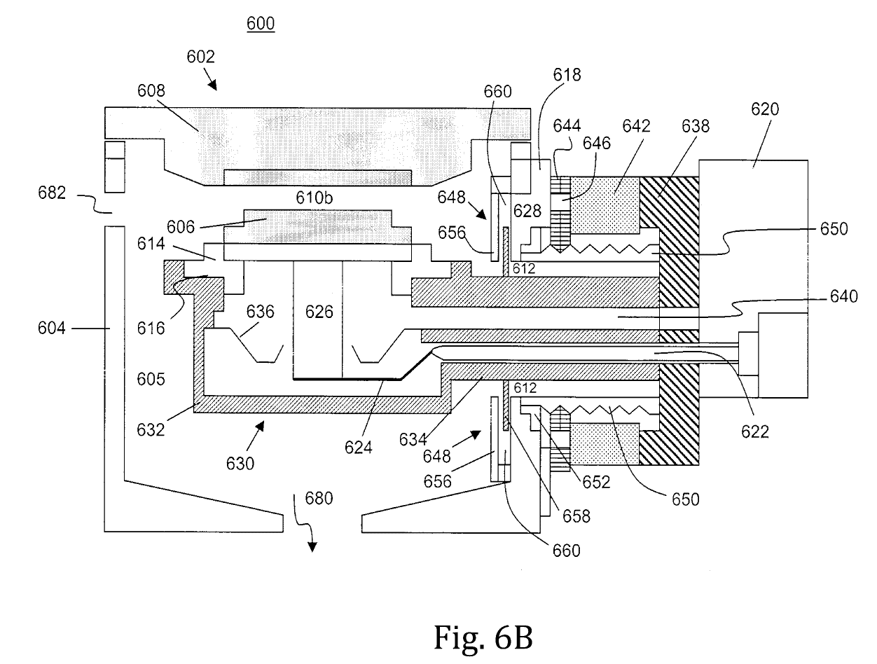

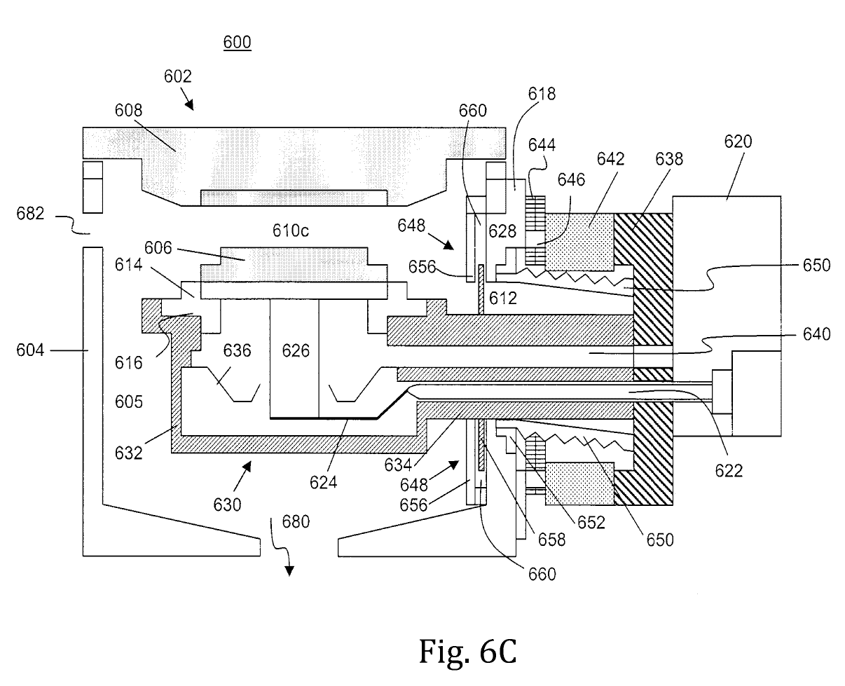

For instance, FIGS. 6A-6C illustrate an embodiment of an adjustable gap capacitively coupled confined RF plasma reactor 600. As depicted, a vacuum processing chamber 602 includes a chamber housing 604, surrounding an interior space housing a lower electrode 606. In an upper portion of the chamber 602 an upper electrode 608 is vertically spaced apart from the lower electrode 606. Planar surfaces of the upper and lower electrodes 608, 606 (configured to be used for plasma generation) are substantially parallel and orthogonal to the vertical direction between the electrodes. Preferably the upper and lower electrodes 608, 606 are circular and coaxial with respect to a vertical axis. A lower surface of the upper electrode 608 faces an upper surface of the lower electrode 606. The spaced apart facing electrode surfaces define an adjustable gap 610 there between. During plasma generation, the lower electrode 606 is supplied RF power by an RF power supply (match) 620. RF power is supplied to the lower electrode 606 though an RF supply conduit 622, an RF strap 624 and an RF power member 626. A grounding shield 636 may surround the RF power member 626 to provide a more uniform RF field to the lower electrode 606. As described in U.S. Pat. Pub. No. 2008/0171444 (which is hereby incorporated by reference in its entirety for all purposes), a wafer is inserted through wafer port 682 and supported in the gap 610 on the lower electrode 606 for processing, a process gas is supplied to the gap 610 and excited into plasma state by the RF power. The upper electrode 608 can be powered or grounded.

In the embodiment shown in FIGS. 6A-6C, the lower electrode 606 is supported on a lower electrode support plate 616. An insulator ring 614 interposed between the lower electrode 606 and the lower electrode support plate 616 insulates the lower electrode 606 from the support plate 616. An RF bias housing 630 supports the lower electrode 606 on an RF bias housing bowl 632. The bowl 632 is connected through an opening in a chamber wall plate 618 to a conduit support plate 638 by an arm 634 of the RF bias housing 630. In a preferred embodiment, the RF bias housing bowl 632 and RF bias housing arm 634 are integrally formed as one component, however, the arm 634 and bowl 632 can also be two separate components bolted or joined together.

The RF bias housing arm 634 includes one or more hollow passages for passing RF power and facilities, such as gas coolant, liquid coolant, RF energy, cables for lift pin control, electrical monitoring and actuating signals from outside the vacuum chamber 602 to inside the vacuum chamber 602 at a space on the backside of the lower electrode 606. The RF supply conduit 622 is insulated from the RF bias housing arm 634, the RF bias housing arm 634 providing a return path for RF power to the RF power supply 620. A facilities conduit 640 provides a passageway for facility components. Further details of the facility components are described in U.S. Pat. No. 5,948,704 and U.S. Pat. Pub. No. 2008/0171444 (both of which are hereby incorporated by reference in their entirety for all purposes) and are not shown here for simplicity of description. The gap 610 is preferably surrounded by a confinement ring assembly (not shown), details of which can be found in U.S. Pat. Pub. No. 2007/0284045 (which is hereby incorporated by reference in its entirety for all purposes).

The conduit support plate 638 is attached to an actuation mechanism 642. Details of an actuation mechanism are described in U.S. Pat. Pub. No. 2008/0171444 (which is hereby incorporated by reference in its entirety for all purposes). The actuation mechanism 642, such as a servo mechanical motor, stepper motor or the like is attached to a vertical linear bearing 644, for example, by a screw gear 646 such as a ball screw and motor for rotating the ball screw. During operation to adjust the size of the gap 610, the actuation mechanism 642 travels along the vertical linear bearing 644. FIG. 6A illustrates the arrangement when the actuation mechanism 642 is at a high position on the linear bearing 644 resulting in a small gap 610a. FIG. 6B illustrates the arrangement when the actuation mechanism 642 is at a mid-position on the linear bearing 644. As shown, the lower electrode 606, the RF bias housing 630, the conduit support plate 638, the RF power supply 620 have all moved lower with respect to the chamber housing 604 and the upper electrode 608, resulting in a medium size gap 610b.

FIG. 6C illustrates a large gap 610c when the actuation mechanism 642 is at a low position on the linear bearing. Preferably, the upper and lower electrodes 608, 606 remain coaxial during the gap adjustment and the facing surfaces of the upper and lower electrodes across the gap remain parallel.

This embodiment allows the gap 610 between the lower and upper electrodes 606, 608 in the CCP chamber 602 during multi-step etch processes to be adjusted, for example, in order to maintain uniform etch across a large diameter substrate such as 300 mm wafers or flat panel displays. In particular, this embodiment pertains to a mechanical arrangement to facilitate the linear motion necessary to provide the adjustable gap between lower and upper electrodes 606, 608.

FIG. 6A illustrates laterally deflected bellows 650 sealed at a proximate end to the conduit support plate 638 and at a distal end to a stepped flange 628 of chamber wall plate 618. The inner diameter of the stepped flange defines an opening 612 in the chamber wall plate 618 through which the RF bias housing arm 634 passes. The laterally deflected bellows 650 provides a vacuum seal while allowing vertical movement of the RF bias housing 630, conduit support plate 638 and actuation mechanism 642. The RF bias housing 630, conduit support plate 638 and actuation mechanism 642 can be referred to as a cantilever assembly. Preferably, the RF power supply 620 moves with the cantilever assembly and can be attached to the conduit support plate 638. FIG. 6B shows the bellows 650 in a neutral position when the cantilever assembly is at a mid-position. FIG. 6C shows the bellows 650 laterally deflected when the cantilever assembly is at a low position.

A labyrinth seal 648 provides a particle barrier between the bellows 650 and the interior of the plasma processing chamber housing 604. A fixed shield 656 is immovably attached to the inside inner wall of the chamber housing 604 at the chamber wall plate 618 so as to provide a labyrinth groove 660 (slot) in which a movable shield plate 658 moves vertically to accommodate vertical movement of the cantilever assembly. The outer portion of the movable shield plate 658 remains in the slot at all vertical positions of the lower electrode 606.

In the embodiment shown, the labyrinth seal 648 includes a fixed shield 656 attached to an inner surface of the chamber wall plate 618 at a periphery of the opening 612 in the chamber wall plate 618 defining a labyrinth groove 660. The movable shield plate 658 is attached and extends radially from the RF bias housing arm 634 where the arm 634 passes through the opening 612 in the chamber wall plate 618. The movable shield plate 658 extends into the labyrinth groove 660 while spaced apart from the fixed shield 656 by a first gap and spaced apart from the interior surface of the chamber wall plate 618 by a second gap allowing the cantilevered assembly to move vertically. The labyrinth seal 648 blocks migration of particles spalled from the bellows 650 from entering the vacuum chamber interior and blocks radicals from process gas plasma from migrating to the bellows 650 where the radicals can form deposits which are subsequently spalled.

FIG. 6A shows the movable shield plate 658 at a higher position in the labyrinth groove 660 above the RF bias housing arm 634 when the cantilevered assembly is in a high position (small gap 610a). FIG. 6C shows the movable shield plate 658 at a lower position in the labyrinth groove 660 above the RF bias housing arm 634 when the cantilevered assembly is in a low position (large gap 610c). FIG. 6B shows the movable shield plate 658 in a neutral or mid position within the labyrinth groove 660 when the cantilevered assembly is in a mid position (medium gap 610b). While the labyrinth seal 648 is shown as symmetrical about the RF bias housing arm 634, in other embodiments the labyrinth seal 648 may be asymmetrical about the RF bias arm 634.

Inductively Coupled Plasma Reactors for Use in Etch Operations

A phased-array of microwave antennas (PAMA) and the microwave focusing techniques disclosed herein may also be employed in an inductively coupled plasma (ICP) reactor, again to adjust and/or control local plasma density near the substrate surface, as described above. Even further description of ICP reactors may be found in US Pat. Pub. No. 2014/0170853, filed Dec. 10, 2013, and titled “IMAGE REVERSAL WITH AHM GAP FILL FOR MULTIPLE PATTERNING,” and in U.S. patent application Ser. No. 14/539,121, filed Nov. 12, 2014, and titled “ADJUSTMENT OF VUV EMISSION OF A PLASMA VIA COLLISIONAL RESONANT ENERGY TRANSFER TO AN ENERGY ABSORBER GAS,” each of which is hereby incorporated by reference in its entirety for all purposes.

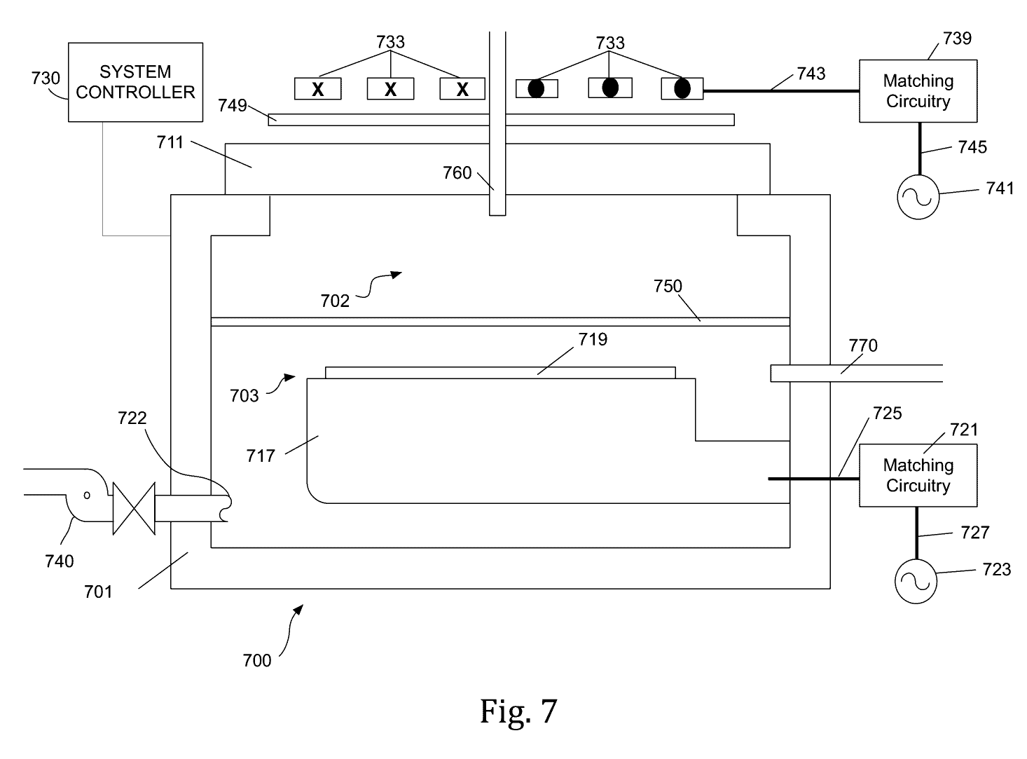

For instance, FIG. 7 schematically shows a cross-sectional view of an inductively coupled plasma etching apparatus 700 appropriate for implementing certain embodiments herein, an example of which is a Kiyo™ reactor, produced by Lam Research Corp. of Fremont, Calif. The inductively coupled plasma etching apparatus 700 includes an overall etching chamber structurally defined by chamber walls 701 and a window 711. The chamber walls 701 may be fabricated from stainless steel or aluminum. The window 711 may be fabricated from quartz, ceramic, or other dielectric material. An optional internal plasma grid 750 divides the overall etching chamber into an upper sub-chamber 702 and a lower sub-chamber 703. In most embodiments, plasma grid 750 may be removed, thereby utilizing a chamber space made of sub-chambers 702 and 703. A chuck 717 is positioned within the lower sub-chamber 703 near the bottom inner surface. The chuck 717 is configured to receive and hold a semiconductor wafer 719 upon which the etching process is performed. The chuck 717 can be an electrostatic chuck for supporting the wafer 719 when present. In some embodiments, an edge ring (not shown) surrounds chuck 717, and has an upper surface that is approximately planar with a top surface of a wafer 719, when present over chuck 717. The chuck 717 also includes electrostatic electrodes for chucking and dechucking the wafer. A filter and DC clamp power supply (not shown) may be provided for this purpose. Other control systems for lifting the wafer 719 off the chuck 717 can also be provided. The chuck 717 can be electrically charged using an RF power supply 723. The RF power supply 723 is connected to matching circuitry 721 through a connection 727. The matching circuitry 721 is connected to the chuck 717 through a connection 725. In this manner, the RF power supply 723 is connected to the chuck 717.

Elements for plasma generation include a coil 733 is positioned above window 711. The coil 733 is fabricated from an electrically conductive material and includes at least one complete turn. The example of a coil 733 shown in FIG. 7 includes three turns. The cross-sections of coil 733 are shown with symbols, and coils having an “X” extend rotationally into the page, while coils having a “” extend rotationally out of the page. Elements for plasma generation also include an RF power supply 741 configured to supply RF power to the coil 733. In general, the RF power supply 741 is connected to matching circuitry 739 through a connection 745. The matching circuitry 739 is connected to the coil 733 through a connection 743. In this manner, the RF power supply 741 is connected to the coil 733. An optional Faraday shield 749 is positioned between the coil 733 and the window 711. The Faraday shield 749 is maintained in a spaced apart relationship relative to the coil 733. The Faraday shield 749 is disposed immediately above the window 711. The coil 733, the Faraday shield 749, and the window 711 are each configured to be substantially parallel to one another. The Faraday shield may prevent metal or other species from depositing on the dielectric window of the plasma chamber.

Process gases (e.g. helium, neon, etchant, etc.) may be flowed into the processing chamber through one or more main gas flow inlets 760 positioned in the upper chamber and/or through one or more side gas flow inlets 770. Likewise, though not explicitly shown, similar gas flow inlets may be used to supply process gases to the capacitively coupled plasma processing chamber shown in FIGS. 6A-6C. A vacuum pump, e.g., a one or two stage mechanical dry pump and/or turbomolecular pump 740, may be used to draw process gases out of the process chamber 724 and to maintain a pressure within the process chamber 700. A valve-controlled conduit may be used to fluidically connect the vacuum pump to the processing chamber so as to selectively control application of the vacuum environment provided by the vacuum pump. This may be done employing a closed-loop-controlled flow restriction device, such as a throttle valve (not shown) or a pendulum valve (not shown), during operational plasma processing. Likewise, a vacuum pump and valve controlled fluidic connection to the capacitively coupled plasma processing chamber in FIGS. 6A-6C may also be employed.

During operation of the apparatus, one or more process gases may be supplied through the gas flow inlets 760 and/or 770. In certain embodiments, process gas may be supplied only through the main gas flow inlet 760, or only through the side gas flow inlet 770. In some cases, the gas flow inlets shown in the figure may be replaced more complex gas flow inlets, one or more showerheads, for example. The Faraday shield 749 and/or optional grid 750 may include internal channels and holes that allow delivery of process gases to the chamber. Either or both of Faraday shield 749 and optional grid 750 may serve as a showerhead for delivery of process gases.

Radio frequency power is supplied from the RF power supply 741 to the coil 733 to cause an RF current to flow through the coil 733. The RF current flowing through the coil 733 generates an electromagnetic field about the coil 733. The electromagnetic field generates an inductive current within the upper sub-chamber 702. The physical and chemical interactions of various generated ions and radicals with the wafer 719 selectively etch features of the wafer.

If the plasma grid is used such that there is both an upper sub-chamber 702 and a lower sub-chamber 703, the inductive current acts on the gas present in the upper sub-chamber 702 to generate an electron-ion plasma in the upper sub-chamber 702. The optional internal plasma grid 750 limits the amount of hot electrons in the lower sub-chamber 703. In some embodiments, the apparatus is designed and operated such that the plasma present in the lower sub-chamber 703 is an ion-ion plasma.

Both the upper electron-ion plasma and the lower ion-ion plasma may contain positive and negative ions, through the ion-ion plasma will have a greater ratio of negative ions to positive ions. Volatile etching byproducts may be removed from the lower-subchamber 703 through port 722.

The chuck 717 disclosed herein may operate at elevated temperatures ranging between about 10° C. and about 250° C. The temperature will depend on the etching process operation and specific recipe. In some embodiments, the chamber 701 may also operate at pressures in the range of between about 1 mTorr and about 95 mTorr. In certain embodiments, the pressure may be higher as disclosed above.

Chamber 701 may be coupled to facilities (not shown) when installed in a clean room or a fabrication facility. Facilities include plumbing that provide processing gases, vacuum, temperature control, and environmental particle control. These facilities are coupled to chamber 701, when installed in the target fabrication facility. Additionally, chamber 701 may be coupled to a transfer chamber that allows robotics to transfer semiconductor wafers into and out of chamber 701 using typical automation.

In some embodiments, a system controller 730—as described below, for example—which may include one or more physical or logical controllers, may control some or all of the operations of an etching chamber, including operation of the one or more phased-arrays of microwave antennas associated with the process stations, including controlling the phases and/or amplitudes and/or directions of the microwave radiation emitted from each antenna of the PAMAs to provide one or more steerable beams of microwave radiation for adjusting and/or controlling local plasma density (and reaction rates) as described above. The system controller 730 may include one or more memory devices and one or more processors.

Cluster Tool having an Integrated Metrology Tool.

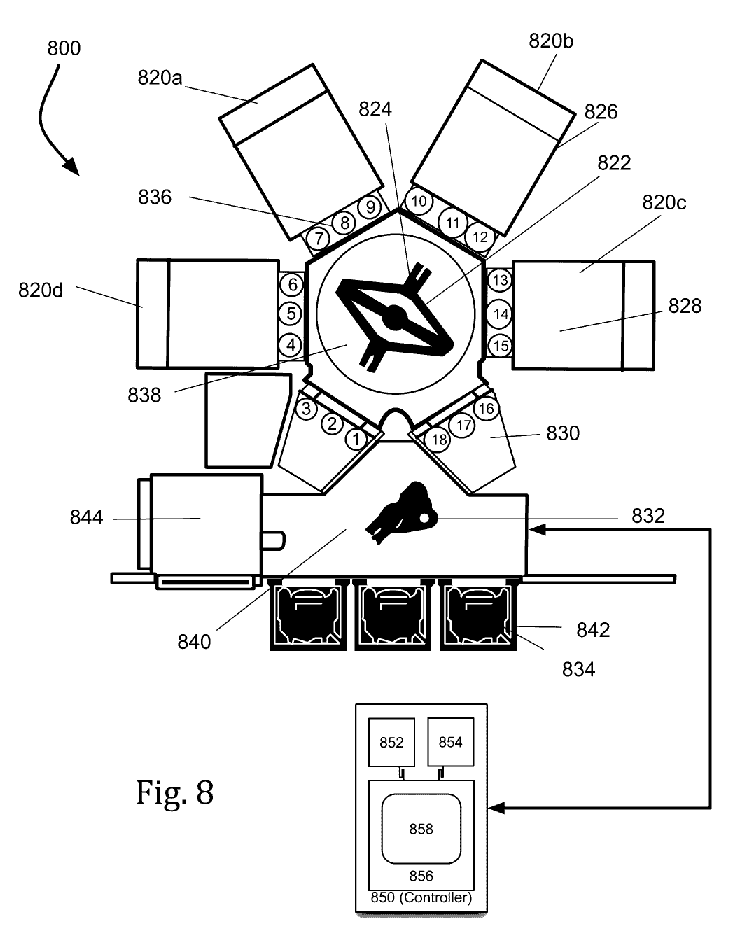

FIG. 8 depicts a semiconductor process cluster tool 800 with various modules that interface with a vacuum transfer module 838 (VTM). The arrangement of transfer modules to “transfer” wafers among multiple storage facilities and processing modules may be referred to as a “cluster tool architecture” system. Airlock 830, also known as a loadlock or transfer module, is shown in VTM 838 with four processing modules 820a-820d, which may be individual optimized to perform various fabrication processes.

For example, processing modules 820a-820d may be implemented to perform substrate etching (such as etching of patterns in single and two-dimensions via an ALE process), deposition (such as deposition of conformal films via an atomic layer deposition (ALD) process), ion implantation, wafer cleaning, wafer planarization, sputtering, and/or other semiconductor processes. Thus, for example, a processing module may be an inductively coupled plasma reactor (as described above), or a capacitively coupled plasma reactor (as also described above).

In some embodiments, one or more of the substrate processing modules (any of 820a-820d) may be dedicated to acquiring wafer metrology data which may be used as a basis for adjusting and/or controlling the operation(s) of the other wafer processing modules on the cluster tool. For example, a wafer metrology tool module may measure one or more properties of one or more substrate features after an etch operation, and the resulting data may then be used to adjust process parameters—such as, for instance, the relative proportions of helium and neon in the plasma used to activate an ALE process—in further etch operations taking place on the cluster tool. In certain such embodiments, the substrate feature measured by the metrology module/tool may be an etch profile of a feature of a semiconductor substrate.

In some etch operations performed on a cluster tool like the one shown in FIG. 8, measurements may be made during an etch operation, and the measurement may be analyzed in order to determine how to adjust and/or control one or more process parameters while the same etch is in progress and/or in a subsequent etch operation (e.g., on a different substrate). For instance, an inductively coupled plasma reactor or a capacitively coupled plasma reactor may employ an optical detector for measuring an emission intensity from one or more visible, infrared, ultraviolet (UV), and/or vacuum ultraviolet (VUV) emission bands, for example, from the plasma used to activate the ALE surface reaction. In some embodiments, the measured emission intensity may be analyzed and used to adjust the relative concentrations of helium and neon in the helium-neon plasma used in the ALE operation as described herein.

Referring again to FIG. 8, airlock 830 and process module 820 may be referred to as “stations.” Each station has a facet 836 that interfaces the station to VTM 838. Inside each facet, sensors 1-18 are used to detect the passing of wafer 826 when moved between respective stations. Robot 822 transfers wafer 826 between stations. In one embodiment, robot 822 has one arm, and in another embodiment, robot 822 has two arms, where each arm has an end effector 824 to pick wafers such as wafer 826 for transport. Front-end robot 832, in atmospheric transfer module (ATM) 840, is used to transfer wafers 826 from cassette or Front Opening Unified Pod (FOUP) 834 in Load Port Module (LPM) 842 to airlock 830. Module center 828 inside process module 820 is one location for placing wafer 826. Aligner 844 in ATM 840 is used to align wafers.

In one example of a processing sequence, a wafer is placed in one of the FOUPs 834 in the LPM 842. Front-end robot 832 transfers the wafer from the FOUP 834 to an aligner 844, which allows the wafer 826 to be properly centered before it is etched or processed. After being aligned, the wafer 826 is moved by the front-end robot 832 into an airlock 830. Because airlock modules have the ability to match the environment between an ATM and a VTM, the wafer 826 is able to move between the two pressure environments without being damaged. From the airlock module 830, the wafer 826 is moved by robot 822 through VTM 838 and into one of the process modules 820a-820d. In order to achieve this wafer movement, the robot 822 uses end effectors 824 on each of its arms. Once the wafer 826 has been processed, it is moved by robot 822 from the process modules 820a-820d to an airlock module 830. From here, the wafer 826 may be moved by the front-end robot 832 to one of the FOUPs 834 or to the aligner 844.

It should be noted that a system controller (as described below) may be used to control the operation of the cluster tool (e.g., to control substrate movement amongst the various stations on the cluster tool). The system controller may be local to the cluster architecture, or it may be located external to the cluster tool in the manufacturing floor, or in a remote location and connected to the cluster tool via a network.

### System Controllers

A system controller may be used to control deposition or etching operations (or other processing operations) in any of the above described processing apparatuses. In particular, the system controller may control the operation of the one or more phased-arrays of microwave antennas associated with the process stations, including controlling the phases and/or amplitudes and/or directions of the microwave radiation emitted from each antenna of the arrays to provide one or more steerable beams of microwave radiation for adjusting and/or controlling local plasma density (and reaction rates, dep or etch) as described above.

Thus, for instance, with respect to a deposition apparatus, such as that shown in FIG. 4B, a system controller 450 may be employed to control process conditions and hardware states of process tool 440 and its process stations. System controller 450 may include one or more memory devices 456, one or more mass storage devices 454, and one or more processors 452. Processor 452 may include one or more CPUs, ASICs, general-purpose computer(s) and/or specific purpose computer(s), one or more analog and/or digital input/output connection(s), one or more stepper motor controller board(s), etc.

Likewise, a system controller may be employed with respect to a semiconductor substrate etching apparatus (whether it constitutes a CCP or an ICP reactor); and likewise, such a system controller may control the operation of the one or more phased-arrays of microwave antennas associated with one or more process stations of the etch reactor, including controlling the phases and/or amplitudes and/or directions of the microwave radiation emitted from each antenna of the arrays to provide one or more steerable beams of microwave radiation for adjusting and/or controlling local plasma density as described above.

Thus, FIG. 8 depicts an embodiment of a system controller 850 employed to control process conditions and hardware states of etch process tool 800 and its process stations. System controller 850 may include one or more memory devices 856, one or more mass storage devices 854, and one or more processors 852. Processor 852 may include one or more CPUs, ASICs, general-purpose computer(s) and/or specific purpose computer(s), one or more analog and/or digital input/output connection(s), one or more stepper motor controller boa rd(s), etc.

In some embodiments, a system controller (450, FIG. 4B; 850, FIG. 8) controls some or all of the operations of a process tool (450, FIG. 4B; 800 FIG. 8) including the operations of its individual process stations. Machine-readable system control instructions (458, FIG. 4B; 858, FIG. 8) may be provided for implementing/performing the film deposition and/or etch processes described herein. The instructions may be provided on machine-readable, non-transitory media which may be coupled to and/or read by the system controller. The instructions may be executed on processor (452, FIG. 4B; 852, FIG. 8)—the system control instructions, in some embodiments, loaded into memory device (456, 856) from mass storage device (454, 854). System control instructions may include instructions for controlling the timing, mixture of gaseous and liquid reactants, chamber and/or station pressures, chamber and/or station temperatures, wafer temperatures, target power levels, RF power levels (e.g., DC power levels, RF bias power levels), RF exposure times, substrate pedestal, chuck, and/or susceptor positions, and other parameters of a particular process performed by a process tool. It may also include instructions for operating the one or more phased-arrays of microwave antennas associated with the process stations, as described above.

Semiconductor substrate processing operations may employ various types of processes including, but not limited to, processes related to the etching of film on substrates (such as by atomic layer etch (ALE) operations involving plasma-activation of surface adsorbed etchants, see, e.g., U.S. patent application Ser. No. 14/539,121, filed Nov. 12, 2014, and titled “ADJUSTMENT OF VUV EMISSION OF A PLASMA VIA COLLISIONAL RESONANT ENERGY TRANSFER TO AN ENERGY ABSORBER GAS,” which is hereby incorporated by reference in its entirety for all purposes), deposition processes (such as atomic layer deposition (ALD), by plasma-activation of surface adsorbed film precursors), as well as other types of substrate processing operations.

Thus, for example, with respect to a substrate processing apparatus for performing plasma-based etch or deposition processes that has one or more phased-arrays of microwave antennas, the machine-readable instructions executed by a system controller may include instructions for operating a plasma generator configured to generate a plasma within the processing chamber, and also instructions for operating one or more phased-arrays of microwave antennas which are configured to emit a beam of microwave radiation into the chamber and thus to affect the plasma within the processing chamber. In some embodiments, the controller may operate the one or more phased-arrays of microwave antennas so as to steer the emitted beam of microwave radiation. The controller may do so by varying the relative phases of the microwave radiation emitted from two or more antennas of the one or more phased-arrays. The controller may also vary the relative magnitudes of the microwave radiation emitted from two or more antennas of the one or more phased-arrays. Additionally, in some embodiments, a substrate processing apparatus may have an optical detector for measuring an optical discharge from the plasma used in a plasma-based processing operation, and the controller may operate the optical detector to measure an emission intensity of an emission band of the plasma, and in certain such embodiments, in response to said measurement, vary said phases and/or magnitudes and/or directions of the microwave radiation emitted from phased-array(s) (and/or adjust other process conditions as well).

System control instructions (458, FIG. 4B; 858, FIG. 8) may be configured in any suitable way. For example, various process tool component subroutines or control objects may be written to control operation of the process tool components necessary to carry out various process tool processes. System control instructions may be coded in any suitable computer readable programming language. In some embodiments, system control instructions are implemented in software, in other embodiments, the instructions may be implemented in hardware—for example, hard-coded as logic in an ASIC (application specific integrated circuit), or, in other embodiments, implemented as a combination of software and hardware.

In some embodiments, system control software (458 in FIG. 4B, 858 in FIG. 8) may include input/output control (IOC) sequencing instructions for controlling the various parameters described above. For example, each phase of a deposition and/or etch process or processes may include one or more instructions for execution by the system controller. The instructions for setting process conditions for a film deposition and/or etch process phase, for example, may be included in a corresponding deposition and/or etch recipe phase. In some embodiments, the recipe phases may be sequentially arranged, so that all instructions for a process phase are executed concurrently with that process phase.

Other computer-readable instructions and/or programs stored on mass storage device 854 and/or memory device 856 associated with system controller 850 (or with respect to FIG. 4B, on mass storage device 454 and/or memory device 456 associated with system controller 450) may be employed in some embodiments. Examples of programs or sections of programs include a substrate positioning program, a process gas control program, a pressure control program, a heater control program, and a plasma control program.

A substrate positioning program may include instructions for process tool components that are used to load the substrate onto pedestal (see, e.g., 408, FIG. 4B; see also, e.g., 508, FIG. 5) and to control the spacing between the substrate and other parts of process tool. The positioning program may include instructions for appropriately moving substrates in and out of the reaction chamber as necessary to deposit and/or etch film on the substrates.

A process gas control program may include instructions for controlling gas composition and flow rates and optionally for flowing gas into the volumes surrounding one or more process stations prior to deposition and/or etch in order to stabilize the pressure in these volumes. In some embodiments, the process gas control program may include instructions for introducing certain gases into the volume(s) surrounding the one or more process stations within a processing chamber during film deposition and/or etching operations on substrates. The process gas control program may also include instructions to deliver these gases at the same rates, for the same durations, or at different rates and/or for different durations depending on the composition of the film being deposited and/or the nature of the etching process involved. The process gas control program may also include instructions for atomizing/vaporizing a liquid reactant in the presence of helium or some other carrier gas in a heated injection module.

A pressure control program may include instructions for controlling the pressure in the process station by regulating, for example, a throttle valve in the exhaust system of the process station, a gas flow into the process station, etc. The pressure control program may include instructions for maintaining the same or different pressures during deposition of the various film types on the substrates and/or etching of the substrates.

A heater control program may include instructions for controlling the current to a heating unit that is used to heat the substrates. Alternatively or in addition, the heater control program may control delivery of a heat transfer gas (such as helium) to the substrate. The heater control program may include instructions for maintaining the same or different temperatures in the reaction chamber and/or volumes surrounding the process stations during deposition of the various film types on the substrates and/or etching of the substrates.

A plasma control program may include instructions for setting RF power levels, frequencies, and exposure times in one or more process stations in accordance with the embodiments herein. In some embodiments, the plasma control program may include instructions for using the same or different RF power levels and/or frequencies and/or exposure times during film deposition on and/or etching of the substrates.

In some embodiments, there may be a user interface associated with the system controller. The user interface may include a display screen, graphical software displays of the apparatus and/or process conditions, and user input devices such as pointing devices, keyboards, touch screens, microphones, etc.

In some embodiments, parameters adjusted by system controller may relate to process conditions. Non-limiting examples include process gas compositions and flow rates, temperatures (e.g., substrate holder and showerhead temperatures), pressures, plasma conditions (such as RF bias power levels and exposure times), etc. Additional parameters may relate to the amplitudes and phases of microwave radiation emitted from one or more phased-arrays of microwave antennas. Moreover, the parameters may relate to controlling the amplitude and/or phase and/or direction of microwave radiation emitted from each antenna of the one or more arrays, individually. These parameters may be provided to the user in the form of a recipe, which may be entered utilizing the user interface.

Signals for monitoring the processes may be provided by analog and/or digital input connections of the system controller from various process tool sensors. The signals for controlling the processes may be output on the analog and/or digital output connections of the process tool. Non-limiting examples of process tool sensors that may be monitored include mass flow controllers (MFCs), pressure sensors (such as manometers), temperature sensors such as thermocouples, etc. In etch apparatuses having one or more phased-arrays of microwave antennas for adjusting and/or controlling local plasma density near the wafer surface, the apparatus's sensors may include optical emission sensors for monitoring spectral discharge from the plasma in order to gauge its density and/or power/levels. Appropriately programmed feedback and control algorithms may be used with data from these sensors to maintain process conditions.

The various apparatuses and methods described above may be used in conjunction with lithographic patterning tools and/or processes, for example, for the fabrication or manufacture of semiconductor devices, displays, LEDs, photovoltaic panels and the like. Typically, though not necessarily, such tools will be used or processes conducted together and/or contemporaneously in a common fabrication facility.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module (employing inductively or capacitively coupled plasmas), a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Additional Detailed Description of ALD Techniques and Deposited Films

As discussed above, as IC device size continues to shrink and ICs move to employing 3-D transistors and other 3-D structures, the ability to deposit a precise amount (thickness) of conformal film material—dielectrics in particular, but also various dopant-containing materials—has become increasingly important. Atomic layer deposition (ALD) is one technique for accomplishing conformal film deposition that typically involves multiple cycles of deposition in order to achieve a desired thickness of film.

In contrast with chemical vapor deposition (CVD) process, where activated gas phase reactions are used to deposit films, ALD processes use surface-mediated deposition reactions to deposit films on a layer-by-layer basis. For instance, in one class of ALD processes, a first film precursor (P1) is introduced in a processing chamber in the gas phase, is exposed to a substrate, and is allowed to adsorb onto the surface of the substrate (typically at a population of surface active sites). Some molecules of P1 may form a condensed phase atop the substrate surface, including chemisorbed species and physisorbed molecules of P1. The volume surrounding the substrate surface is then evacuated to remove gas phase and physisorbed P1 so that only chemisorbed species remain. A second film precursor (P2) may then be introduced into the processing chamber so that some molecules of P2 adsorb to the substrate surface. The volume surrounding the substrate within the processing chamber may again be evacuated, this time to remove unbound P2. Subsequently, energy provided to the substrate (e.g., thermal or plasma energy) activates surface reactions between the adsorbed molecules of P1 and P2, forming a film layer. Finally, the volume surrounding the substrate is again evacuated to remove unreacted P1 and/or P2 and/or reaction by-product, if present, ending a single cycle of ALD.

ALD techniques for depositing conformal films having a variety of chemistries—and also many variations on the basic ALD process sequence—are described in detail in U.S. patent application Ser. No. 13/084,399, filed Apr. 11, 2011, titled “PLASMA ACTIVATED CONFORMAL FILM DEPOSITION” (Attorney Docket No. NOVLP405), U.S. patent application Ser. No. 13/242,084, filed Sep. 23, 2011, titled “PLASMA ACTIVATED CONFORMAL DIELECTRIC FILM DEPOSITION,” now U.S. Pat. No. 8,637,411 (Attorney Docket No. NOVLP427), U.S. patent application Ser. No. 13/224,240, filed Sep. 1, 2011, titled “PLASMA ACTIVATED CONFORMAL DIELECTRIC FILM DEPOSITION” (Attorney Docket No. NOVLP428), and U.S. patent application Ser. No. 13/607,386, filed Sep. 7, 2012, titled “CONFORMAL DOPING VIA PLASMA ACTIVATED ATOMIC LAYER DEPOSITION AND CONFORMAL FILM DEPOSITION” (Attorney Docket No. NOVLP488), each of which is incorporated by reference herein in its entirety for all purposes. As described in these prior applications, a basic ALD cycle for depositing a single layer of material on a substrate may include: (i) adsorbing a film precursor onto a substrate at a process station such that it forms an adsorption-limited layer, (ii) removing, when present, unadsorbed precursor (“unadsorbed precursor” defined to include desorbed precursor) from the vicinity of the process station, (iii) reacting the adsorbed-precursor to form a layer of film on the substrate, and optionally (iv) removing desorbed film precursor and/or reaction by-product from the vicinity of the process station. The removing in operations (ii) and (iv) may be done via purging, evacuating, pumping down to a base pressure (“pump-to-base”), etc. the volume surrounding the substrate. In some embodiments, the purge gas may be the same as the main plasma feed gas. The foregoing sequence of operations (i) through (iv) represent a single ALD cycle resulting in the formation of a single layer of film. However, since an single layer of film formed via ALD is typically very thin—often it is only a single molecule thick—multiple ALD cycles are repeated in sequence to build up a film of appreciable thickness. Thus, if it is desired that a film of say N layers be deposited (or, equivalently, one might say N layers of film), then multiple ALD cycles (operations (i) through (iv)) may be repeated in sequence N times.

It is noted that this basic ALD sequence of operations (i) through (iv) doesn't necessary involve two chemiadsorbed reactive species P1 and P2 as in the example described above, nor does it even necessarily involve a second reactive species, although these possibilities/options may be employed, depending on the desired deposition chemistries involved.

Due to the adsorption-limited nature of ALD, however, a single cycle of ALD only deposits a thin film of material, and oftentimes only a single monolayer of material. For example, depending on the exposure time of the film precursor dosing operations and the sticking coefficients of the film precursors (to the substrate surface), each ALD cycle may deposit a film layer only about 0.5 to 3 Angstroms thick. Thus, the sequence of operations in a typical ALD cycle—operations (i) through (iv) just described—are generally repeated multiple times in order to form a conformal film of the desired thickness. Thus, in some embodiments, operations (i) through (iv) are repeated consecutively at least 1 time, or at least 2 times, or at least 3 times, or at least 5 times, or at least 7 times, or at least 10 times in a row. An ALD film may be deposited at a rate of about or between 0.1 Å and 2.5 Å per ALD cycle, or about or between 0.2 Å and 2.0 Å per ALD cycle, or about or between 0.3 Å and 1.8 Å per ALD cycle, or about or between 0.5 Å and 1.5 Å per ALD cycle, or about or between 0.1 Å and 1.5 Å per ALD cycle, or about or between 0.2 Å and 1.0 Å per ALD cycle, or about or between 0.3 Å and 1.0 Å per ALD cycle, or about or between 0.5 Å and 1.0 Å per ALD cycle.

In some film forming chemistries, an auxiliary reactant or co-reactant—in addition to what is referred to as the “film precursor”—may also be employed. In certain such embodiments, the auxiliary reactant or co-reactant may be flowed continuously during a subset of steps (i) through (iv) or throughout each of steps (i) through (iv) as they are repeated. In some embodiments, this other reactive chemical species (auxiliary reactant, co-reactant, etc.) may be adsorbed onto the substrate surface with the film precursor prior to its reaction with the film precursor (as in the example involving precursors P1 and P2 described above), however, in other embodiments, it may react with the adsorbed film precursor as it contacts it without prior adsorption onto the surface of the substrate, per se. Also, in some embodiments, operation (iii) of reacting the adsorbed film precursor may involve contacting the adsorbed film precursor with a plasma. The plasma may provide energy to drive the film-forming reaction on the substrate surface. In certain such embodiments, the plasma may be an oxidative plasma generated in the reaction chamber with application of suitable RF power (although in some embodiments, it may be generated remotely). In other embodiments, instead of an oxidative plasma, an inert plasma may be used. The oxidizing plasma may be formed from one or more oxidants such as O₂, N₂O, or CO₂, and may optionally include one or more diluents such as Ar, N₂, or He. In one embodiment, the oxidizing plasma is formed from O₂ and Ar. A suitable inert plasma may be formed from one or more inert gases such as He or Ar. Further variations on ALD processes are described in detail in the prior patent applications just cited (and which are incorporated by reference).

In some embodiments, a multi-layer deposited film may include regions/portions of alternating composition formed, for example, by conformally depositing multiple layers sequentially having one composition, and then conformally depositing multiple layers sequentially having another composition, and then potentially repeating and alternating these two sequences. Some of these aspects of deposited ALD films are described, for example, in U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488), which is incorporated by reference herein in its entirety for all purposes. Further examples of conformal films having portions of alternating composition—including films used for doping an underlying target IC structure or substrate region—as well as methods of forming these films, are described in detail in: U.S. patent application Ser. No. 13/084,399, filed Apr. 11, 2011, and titled “PLASMA ACTIVATED CONFORMAL FILM DEPOSITION” (Attorney Docket No. NOVLP405); U.S. patent application Ser. No. 13/242,084, filed Sep. 23, 2011, and titled “PLASMA ACTIVATED CONFORMAL DIELECTRIC FILM DEPOSITION,” now U.S. Pat. No. 8,637,411 (Attorney Docket No. NOVLP427); U.S. patent application Ser. No. 13/224,240, filed Sep. 1, 2011, and titled “PLASMA ACTIVATED CONFORMAL DIELECTRIC FILM DEPOSITION” (Attorney Docket No. NOVLP428); U.S. patent application Ser. No. 13/607,386, filed Sep. 7, 2012, and titled “CONFORMAL DOPING VIA PLASMA ACTIVATED ATOMIC LAYER DEPOSITION AND CONFORMAL FILM DEPOSITION” (Attorney Docket No. NOVLP488); and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is incorporated by reference herein in its entirety for all purposes.

As detailed in the above referenced specifications, ALD processes are oftentimes used to deposit conformal silicon oxide films (SiOx), however ALD processes may also be used to deposit conformal dielectric films of other chemistries as also disclosed in the foregoing incorporated specifications. ALD-formed dielectric films may, in some embodiments, contain a silicon carbide (SiC) material, a silicon nitride (SiN) material, a silicon carbonitride (SiCN) material, or a combination thereof. Silicon-carbon-oxides and silicon-carbon-oxynitrides, and silicon-carbon-nitrides may also be formed in some embodiment ALD-formed films. Methods, techniques, and operations for depositing these types of films are described in detail in U.S. patent application Ser. No. 13/494,836, filed Jun. 12, 2012, titled “REMOTE PLASMA BASED DEPOSITION OF SiOC CLASS OF FILMS,” Attorney Docket No. NOVLP466/NVLS003722; U.S. patent application Ser. No. 13/907,699, filed May 31, 2013, titled “METHOD TO OBTAIN SiC CLASS OF FILMS OF DESIRED COMPOSITION AND FILM PROPERTIES,” Attorney Docket No. LAMRPO46/3149; U.S. patent application Ser. No. 14/062,648, titled “GROUND STATE HYDROGEN RADICAL SOURCES FOR CHEMICAL VAPOR DEPOSITION OF SILICON-CARBON-CONTAINING FILMS”; and U.S. patent application Ser. No. 14/194,549, filed Feb. 28, 2014, and titled “CAPPED ALD FILMS FOR DOPING FIN-SHAPED CHANNEL REGIONS OF 3-D IC TRANSISTORS”; each of which is hereby incorporated by reference in its entirety and for all purposes.

Other examples of film deposition via ALD include chemistries for depositing dopant-containing films as described in the patent applications listed and incorporated by reference above (U.S. patent application Ser. Nos. 13/084,399, 13/242,084, 13/224,240, and 14/194,549). As described therein, various dopant-containing film precursors may be used for forming the dopant-containing films, such as films of boron-doped silicate glass (BSG), phosphorous-doped silicate glass (PSG), boron phosphorus doped silicate glass (BPSG), arsenic (As) doped silicate glass (ASG), and the like. The dopant-containing films may include B₂O₃, B₂O, P₂O₅, P₂O₃, As₂O₃, As₂O₅, and the like. Thus, dopant-containing films having dopants other than boron are feasible. Examples include gallium, phosphorous, or arsenic dopants, or other elements appropriate for doping a semiconductor substrate, such as other valence III and V elements.

As for ALD process conditions, ALD processes may be performed at various temperatures. In some embodiments, suitable temperatures within an ALD reaction chamber may range from between about 25° C. and 450° C., or between about 50° C. and 300° C., or between about 20° C. and 400° C., or between about 200° C. and 400° C., or between about 100° C. and 350° C.

Likewise, ALD processes may be performed at various ALD reaction chamber pressures. In some embodiments, suitable pressures within the reaction chamber may range from between about 10 mTorr and 10 Torr, or between about 20 mTorr and 8 Torr, or between about 50 mTorr and 5 Torr, or between about 100 mTorr and 2 Torr.

Various RF power levels may be employed to generate a plasma if used in operation (iii). In some embodiments, suitable RF power may range from between about 100 W and 10 kW, or between about 200 W and 6 kW, or between about 500 W, and 3 kW, or between about 1 kW and 2 kW.

Various film precursor flow rates may be employed in operation (i). In some embodiments, suitable flow rates may range from about or between 0.1 mL/min to 10 mL/min, or about or between 0.5 mL/min and 5 mL/min, or about or between 1 mL/min and 3 mL/min.

Various gas flow rates may be used in the various operations. In some embodiments, general gas flow rates may range from about or between 1 L/min and 20 L/min, or about or between 2 L/min and 10 L/min. For the optional inert purge steps in operations (ii) and (iv), an employed burst flow rate may range from about or between 20 L/min and 100 L/min, or about or between 40 L/min and 60 L/min.

Once again, in some embodiments, a pump-to-base step refers to pumping the reaction chamber to a base pressure by directly exposing it to one or more vacuum pumps. In some embodiments, the base pressure may typically be only a few milliTorr (e.g., between about 1 and 20 mTorr). Furthermore, as indicated above, a pump-to-base step may or may not be accompanied by an inert purge, and thus carrier gases may or may not be flowing when one or more valves open up the conductance path to the vacuum pump.

Also, once again, multiple ALD cycles may be repeated to build up stacks of conformal layers. In some embodiments, each layer may have substantially the same composition whereas in other embodiments, sequentially ALD deposited layers may have differing compositions, or in certain such embodiments, the composition may alternate from layer to layer or there may be a repeating sequence of layers having different compositions, as described above. Thus, depending on the embodiment, certain stack engineering concepts, such as those disclosed in the patent applications listed and incorporated by reference above (U.S. patent application Ser. Nos. 13/084,399, 13/242,084, and 13/224,240) may be used to modulate boron, phosphorus, or arsenic concentration in these films.

### Lithographic Patterning

The various apparatuses and methods described above may be used in conjunction with lithographic patterning tools and/or processes, for example, for the fabrication or manufacture of semiconductor devices, displays, LEDs, photovoltaic panels and the like. Typically, though not necessarily, such tools will be used or processes conducted together and/or contemporaneously in a common fabrication facility.

Lithographic patterning of a film typically includes some or all of the following operations, each operation enabled with a number of possible tools: (1) application of photoresist on a substrate, e.g., a substrate having a silicon nitride film formed thereon, using a spin-on or spray-on tool; (2) curing of photoresist using a hot plate or furnace or other suitable curing tool; (3) exposing the photoresist to visible or UV or x-ray light with a tool such as a wafer stepper; (4) developing the resist so as to selectively remove resist and thereby pattern it using a tool such as a wet bench or a spray developer; (5) transferring the resist pattern into an underlying film or substrate by using a dry or plasma-assisted etching tool; and (6) removing the resist using a tool such as an RF or microwave plasma resist stripper. In some embodiments, an ashable hard mask layer (such as an amorphous carbon layer) and another suitable hard mask (such as an antireflective layer) may be deposited prior to applying the photoresist.

### OTHER EMBODIMENTS

Although the foregoing disclosed techniques, operations, processes, methods, systems, apparatuses, tools, films, chemistries, and compositions have been described in detail within the context of specific embodiments for the purpose of promoting clarity and understanding, it will be apparent to one of ordinary skill in the art that there are many alternative ways of implementing the foregoing embodiments which are within the spirit and scope of this disclosure. Accordingly, the embodiments described herein are to be viewed as illustrative of the disclosed inventive concepts rather than restrictively, and are not to be used as an impermissible basis for unduly limiting the scope of any claims eventually directed to the subject matter of this disclosure.

1.-3. (canceled)

4. A phased-array of microwave antennas, comprising 8-256 microwave antennas arranged substantially cylindrically with respect to each other, the height of said cylindrical arrangement being 5-500 mm, and the diameter of said cylindrical arrangement being 300-600 mm.

5. The phased-array of claim 4, wherein the height of said cylindrical arrangement is 100-300 mm, and the diameter of said cylindrical arrangement is 350-450 mm.

6. The phased-array of claim 5, wherein the mean spacing between adjacent antennas is 0.1-150 cm.

7. The phased-array of claim 6, wherein the cylindrical arrangement comprises a stack of several groups of substantially circularly arranged antennas.

8. The phased-array of claim 7, wherein the cylindrical arrangement comprises a stack of 3-7 groups of substantially circularly arranged antennas.

9. A method of modifying a reaction rate on a semiconductor substrate in a processing chamber, the method comprising:
energizing a plasma in a processing chamber;
emitting a beam of microwave radiation from a phased-array of microwave antennas; and
directing the beam into the plasma so as to cause a change in a reaction rate on the surface of a semiconductor substrate inside the processing chamber.

10. The method of claim 9, further comprising:
steering the beam of microwave energy directed into the plasma so as to modify the effect on the density of the plasma.

11. The method of claim 10, wherein steering the beam comprises varying the relative phases of the microwave radiation emitted from two or more of the microwave antennas of the phased-array.

12. The method of claim 11, wherein steering the beam comprises varying the relative phases and magnitudes of the microwave radiation emitted from two or more of the microwave antennas of the phased-array.

13. (canceled)

14. (canceled)

15. The method of claim 9, wherein the plasma is an inductively-coupled plasma (ICP).

16. The method of claim 9, wherein the plasma is a capacitively-coupled plasma (CCP).

17. (canceled)

18. A semiconductor processing apparatus comprising:
a processing chamber;
a substrate holder configured to hold a semiconductor substrate within the processing chamber;
a plasma generator configured to generate a plasma within the processing chamber;
a phased-array of microwave antennas configured to emit a beam of microwave radiation into the chamber; and
a controller having instructions for operating the phased-array microwave antenna to affect the plasma within the processing chamber.

19. The processing apparatus of claim 18, wherein the controller operates the phased-array microwave antennas so as to steer the emitted beam of microwave radiation.

20. The processing apparatus of claim 18, wherein the controller varies the relative phases of the microwave radiation emitted from two or more antennas of the phased-array.

21. The processing apparatus of claim 20, wherein the controller varies the relative phases and magnitudes of the microwave radiation emitted from two or more antennas of the phased-array.

22. The processing apparatus of claim 18, wherein at least some of the antennas are located around the periphery of the processing chamber.

23. The processing apparatus of claim 18, wherein at least some of the antennas are located above the processing chamber.

24. (canceled)

25. The processing apparatus of claim 18, wherein the plasma generator is configured to generate an inductively-coupled plasma (ICP) and comprises two or more coils connected to one or more power supplies for generating the ICP plasma.

26. (canceled)

27. (canceled)

28. The processing apparatus of claim 18, wherein the plasma generator is configured to generate a capacitively-coupled plasma (CCP) and comprises a plate electrode connected to a power supply for applying a voltage difference between the plate electrode and the substrate holder for generating the CCP plasma.

29. (canceled)

30. (canceled)

31. The processing apparatus of claim 17, wherein the processing chamber comprises a dielectric window through which the microwave energy emitted by the phased-array of antennas is transmitted into the chamber.

32. (canceled)

33. The processing apparatus of claim 31, wherein the dielectric window comprises quartz and/or ceramic.

34. (canceled)

35. (canceled)
